(19) United States
(12) Patent Application Publication
(10) Pub. No.: US 2026/0372012 A1
(43) Pub. Date: Nov. 19, 2026

(54) SUBSTRATE SUPPORT ASSEMBLIES FOR SEMICONDUCTOR PROCESSING APPARATUSES AND METHODS OF OPERATING SUBSTRATE SUPPORT ASSEMBLIES

(71) Applicant: ASM IP Holding B.V., Almere (NL)

(72) Inventors: Qichao Hu, Tempe, AZ (US); Ion Hong Chao, Gilbert, AZ (US); Fan Gao, Chandler, AZ (US); Han Ye, Phoenix, AZ (US); Junwei Su, Chandler, AZ (US); Wentao Wang, Chandler, AZ (US); Bradley Wayne Evans, Apache Junction, AZ (US); Shree Ramalingam Balasubramanian, Chandler, AZ (US); Shujin Huang, Phoenix, AZ (US); Sipan Liu, Tempe, AZ (US)

(21) Appl. No.: 19/754,694

(22) Filed: Jul. 27, 2026

Related U.S. Application Data
(63) Continuation-in-part of application No. 19/195,455, filed on Apr. 30, 2025.
(60) Provisional application No. 63/641,312, filed on May 1, 2024.

(51) Int. Cl. H10P 72/76

(52) U.S. Cl. CPC H10P 72/7612

(57) ABSTRACT

A substrate support assembly for a semiconductor processing apparatus and a method of operating the substrate support assembly are disclosed. The systems disclosed include a substrate support having a support body with an upper surface, an underside surface, a support surface recessed relative to the upper surface, a substrate retaining region, support slots, and lift pin apertures. Lift pins extend through the lift pin apertures with pin clearance relative to guide surfaces defining guide lengths. A lift pin actuator includes pad portions positioned below the lift pins, and a rotation spider includes support arms received by the support slots. The systems disclosed may include a shaft member having planar facets contacted by planar faces of the rotation spider to define a circumferential wedge interface. The methods disclosed include supporting a substrate, moving and guiding the lift pins, supporting the support body, and rotating the shaft member.

### CROSS-REFERENCE TO RELATED APPLICATIONS

This application is a continuation-in-part of U.S. patent application Ser. No. 19/195,455, filed Apr. 30, 2025, which claims the benefit of U.S. Provisional Patent Application No. 63/641,312, filed May 1, 2024. The entire disclosures of the foregoing applications are incorporated herein by reference.

### FIELD

The present disclosure relates generally to the field of semiconductor processing methods and systems and to the field of device and integrated circuit manufacture. More particularly, the present disclosure generally relates to substrate support assemblies for semiconductor processing apparatuses and methods of operating substrate support assemblies during semiconductor processing.

### BACKGROUND OF THE DISCLOSURE

Semiconductor processing systems may support a substrate during deposition, etching, cleaning, annealing, and other processes used in device and integrated circuit manufacture. During such processes, substrate handling may involve lifting, lowering, supporting, and rotating the substrate within a processing chamber while maintaining controlled relationships among the substrate, a substrate support, and associated chamber components.

As substrate size, throughput targets, process-temperature conditions, and film uniformity expectations continue to evolve, substrate handling arrangements may encounter increasingly demanding mechanical and thermal operating conditions. In some processing environments, contact conditions, component tolerances, component wear, and relative movement between substrate handling components can affect repeatability of substrate transfer and can contribute to undesired binding, friction, or positional variation during movement.

Efforts to adapt semiconductor processing systems for different process conditions can also involve changes in substrate support geometry, component spacing, and mechanical interfaces used during lifting and rotation. Such changes may affect manufacturability, assembly, maintenance, chamber operability, and repeatability of substrate positioning. Accordingly, further developments remain of interest in substrate support arrangements and related operating methods for semiconductor processing apparatuses.

Any discussion, including discussion of problems and solutions set forth in this section, has been included in this disclosure solely for the purpose of providing a context for the present disclosure, and should not be taken as an admission that any or all of the discussion was known at the time the present disclosure was made or otherwise constitutes prior art.

### SUMMARY OF THE DISCLOSURE

This summary introduces a selection of concepts in a simplified form, which are described in further detail below. This summary is not intended to identify features of the claimed subject matter and is not intended to be used to limit the scope of the claimed subject matter.

Various embodiments of the present disclosure relate to substrate support assemblies for semiconductor processing apparatuses and methods of operating substrate support assemblies for semiconductor processing apparatuses. The substrate support assemblies may include arrangements for supporting a substrate, moving lift pins relative to a support body, supporting the support body with a rotation spider, and rotating the support body about a rotation axis.

According to one or more embodiments, a substrate support assembly for a semiconductor processing apparatus is provided. The substrate support assembly includes a substrate support, a plurality of lift pins, a lift pin actuator, and a rotation spider. The substrate support includes a support body having an upper surface, an underside surface, a support surface recessed relative to the upper surface, and a body thickness between the upper surface and the underside surface. The support body includes a substrate retaining region disposed radially outward from the support surface, a plurality of support slots recessed from the underside surface, and a plurality of lift pin apertures extending through the support body from respective upper aperture openings at the support surface toward the underside surface. Each lift pin aperture includes a recessed portion at the upper aperture opening and a guide surface extending from the recessed portion toward the underside surface, and the guide surface defines a guide length. Each lift pin extends through one of the lift pin apertures with a pin clearance between the lift pin and the guide surface of the lift pin aperture. The lift pin actuator is positioned adjacent the underside surface of the support body and includes a plurality of pad portions, and each pad portion is positioned below one of the lift pins. The rotation spider is positioned adjacent the underside surface of the support body and includes a plurality of support arms received by the support slots of the support body. For each lift pin and corresponding lift pin aperture, the guide length and the pin clearance are sized to limit tilt of the lift pin relative to the corresponding guide surface during movement of the lift pin by the lift pin actuator.

For each lift pin and corresponding lift pin aperture, the guide length and the pin clearance may define a permitted tilt angle of the lift pin relative to the corresponding guide surface, and the permitted tilt angle may be from about 0.6° to about 3.5°. The body thickness of the support body may be from about 5 mm to about 9 mm. The guide length of each lift pin aperture may be from about 4.5 mm to about 8.5 mm. The lift pin apertures and the support slots may be angularly offset about a rotation axis of the support body. Each lift pin of the plurality of lift pins may have an outer diameter of about 3.5 mm. The support arms of the rotation spider may extend radially outward to the support slots, and the support slots may be arranged about the rotation axis on a support slot diameter of about 326 mm. The lift pin apertures may be arranged radially inward of the support slots. The support body may include a center thermocouple hole extending through the body thickness, and the underside surface may include a substantially planar central region surrounding the center thermocouple hole.

The substrate support assembly may further include a shaft member supported for rotation about a rotation axis. The rotation spider may include a central interface portion including three circumferentially spaced planar faces. The shaft member may have three circumferentially spaced planar facets. Each planar face may contact a corresponding planar facet to define a circumferential wedge interface between the rotation spider and the shaft member. Each planar facet of the shaft member may extend along a respective chordal plane that is laterally offset from the rotation axis. The three circumferentially spaced planar faces and the three circumferentially spaced planar facets may each be oriented at an angle from about 6° to about 15° relative to the rotation axis. The three circumferentially spaced planar faces and the three circumferentially spaced planar facets may each be oriented at an angle of about 10° relative to the rotation axis. The three circumferentially spaced planar faces and the three circumferentially spaced planar facets may define three spaced contact regions that constrain translation and rotation of the rotation spider relative to the shaft member.

According to one or more embodiments, a substrate support assembly for a semiconductor processing apparatus is provided. The substrate support assembly includes a substrate support, a plurality of lift pins, a lift pin actuator, a shaft member, and a rotation spider. The substrate support includes a support body having an upper surface, an underside surface, a support surface recessed relative to the upper surface, and a substrate retaining region disposed radially outward from the support surface. The substrate support includes a plurality of support slots recessed from the underside surface and a plurality of lift pin apertures extending through the support body from respective upper aperture openings at the support surface toward the underside surface. Each lift pin extends through one of the lift pin apertures. The lift pin actuator is positioned adjacent the underside surface of the support body and includes a plurality of pad portions, and each pad portion is positioned below one of the lift pins. The shaft member is supported for rotation about a rotation axis. The rotation spider is positioned adjacent the underside surface of the support body and includes a plurality of support arms received by the support slots of the support body and a central interface portion coupled to the shaft member. The central interface portion includes three circumferentially spaced planar faces, and the shaft member has three circumferentially spaced planar facets. Each of the three circumferentially spaced planar faces contacts a corresponding one of the three circumferentially spaced planar facets to define a circumferential wedge interface between the rotation spider and the shaft member.

Each planar facet of the shaft member may extend along a respective chordal plane that is laterally offset from the rotation axis. The three circumferentially spaced planar faces and the three circumferentially spaced planar facets may each be oriented at an angle from about 6° to about 15° relative to the rotation axis. A weight of the rotation spider may seat the rotation spider on the shaft member with the three circumferentially spaced planar faces bearing against the three circumferentially spaced planar facets. The three circumferentially spaced planar faces and the three circumferentially spaced planar facets may define three spaced contact regions that constrain translation and rotation of the rotation spider relative to the shaft member.

According to one or more embodiments, a method of operating a substrate support assembly for a semiconductor processing apparatus is provided. The method includes supporting a substrate on a support surface of a support body of a substrate support. The support body has an upper surface, an underside surface, a body thickness between the upper surface and the underside surface, a substrate retaining region disposed radially outward from the support surface, a plurality of support slots recessed from the underside surface, and a plurality of lift pin apertures extending through the support body from respective upper aperture openings at the support surface toward the underside surface. Each lift pin aperture includes a recessed portion at the upper aperture opening and a guide surface extending from the recessed portion toward the underside surface, and the guide surface defines a guide length.

The method includes moving a plurality of lift pins through the plurality of lift pin apertures with a lift pin actuator positioned adjacent the underside surface of the support body. The lift pin actuator includes a plurality of pad portions each positioned below a corresponding lift pin of the plurality of lift pins, and each lift pin extends through a corresponding lift pin aperture with a pin clearance between the lift pin and the guide surface of the corresponding lift pin aperture. The method includes guiding each lift pin with the guide surface of the corresponding lift pin aperture over the guide length while the guide length and the pin clearance permit translational movement of the lift pin relative to the corresponding guide surface and limit tilt of the lift pin relative to the corresponding guide surface during movement of the lift pin by the lift pin actuator.

The method includes supporting the support body with a rotation spider positioned adjacent the underside surface of the support body. The rotation spider includes a plurality of support arms received by the plurality of support slots and a central interface portion coupled to a shaft member supported for rotation about a rotation axis. The central interface portion includes three circumferentially spaced planar faces, and the shaft member has three circumferentially spaced planar facets. The method includes rotating the shaft member about the rotation axis while each of the three circumferentially spaced planar faces contacts a corresponding one of the three circumferentially spaced planar facets, thereby rotating the rotation spider and the support body about the rotation axis.

These and other embodiments will become readily apparent to those skilled in the art from the following detailed description of certain embodiments having reference to the attached figures, the present disclosure not being limited to any particular embodiment disclosed.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a lift pin actuator in accordance with the present disclosure, showing the lift pin actuator and an actuator tube member arranged within a chamber arrangement of a semiconductor processing system;

FIG. 2 is a schematic view of a portion of the semiconductor processing system of FIG. 1 according to an example of the present disclosure, showing a process fluid source connected to the chamber arrangement to provide a process fluid to the chamber arrangement;

FIG. 3 is a schematic view of a portion of the semiconductor processing system of FIG. 1 according to an example of the disclosure, showing the chamber arrangement including the lift pin actuator and an actuator tube member seating the lift pin actuator thereon;

FIGS. 4-7 are schematic side views of the chamber arrangement of FIG. 1 according to an example of the disclosure, sequentially showing the lift pin actuator seating a substrate within the chamber arrangement prior to processing and unseating the substrate after processing;

FIG. 8 is a side elevation view of a portion of the chamber arrangement of FIG. 1 including the lift pin actuator according to the present disclosure, showing the lift pin actuator seated on the actuator tube member and a shaft member seating a support member extending through the lift pin actuator and the actuator tube member;

FIG. 9 is an exploded view of a portion of the chamber arrangement of FIG. 1 including the lift pin actuator according to the present disclosure, showing the lift pin actuator and shaft member as well as the support member exploded away from the actuator tube member;

FIGS. 10-12 are views of the lift pin actuator of FIG. 1 according to an example of the present disclosure, showing a pad portion coupled to a hub portion by a first arm portion and a second arm portion of the lift pin actuator;

FIGS. 13 and 14 are lateral and longitudinal cross-sectional views of the lift pin actuator of FIG. 1 according to an example of the present disclosure, showing planar faces with relief channels and arcuate peripheries of the planar faces, respectively;

FIGS. 15 and 16 are side elevation and top plan views of the actuator tube member of FIG. 1 according to an example of the present disclosure, showing a seat end of the actuator tube member having planar facets to seat the lift pin actuator thereon;

FIGS. 17 and 18 are side elevation and top plan views of the seat end of the actuator tube member of FIG. 1 according to an example of the present disclosure, showing a relief channel and the planar face abutting a planar facet of the actuator tube member, respectively;

FIG. 19 is a block diagram of a method of making a lift pin actuator arrangement in accordance with the present disclosure, showing operations of the method according to an illustrative and non-limiting example of the method; and

FIG. 20 is a block diagram of a method of making an actuator arrangement in accordance with the present disclosure, showing operations of the method according to an illustrative and non-limiting example of the method.

FIG. 21 illustrates a cross-sectional view of a support body including a support surface and a lift pin aperture, in accordance with one or more embodiments of the disclosure.

FIG. 22 illustrates an underside view of a support body including support slots and lift pin apertures, in accordance with one or more embodiments of the disclosure.

FIG. 23 illustrates a process flowchart of a method of operating a substrate support assembly for a semiconductor processing apparatus, in accordance with one or more embodiments of the disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

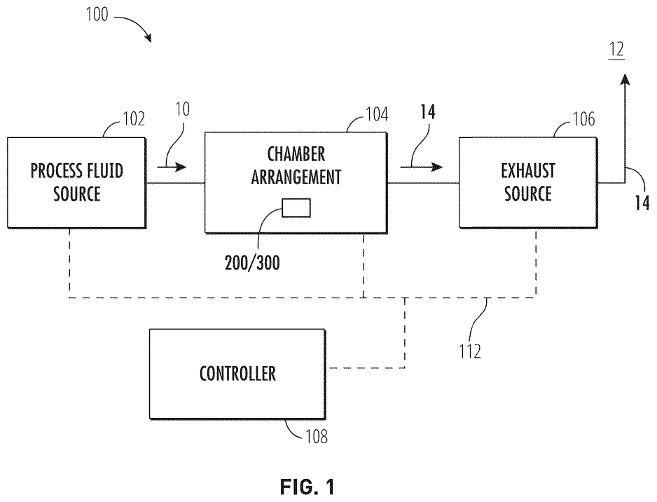

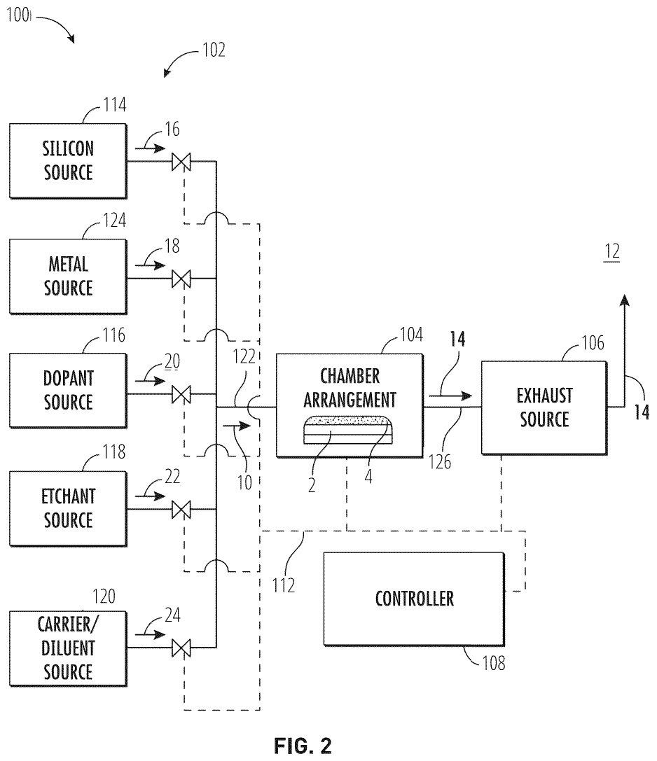

Reference will now be made to the drawings wherein like reference numerals identify similar structural features or aspects of the subject disclosure. For purposes of explanation and illustration, and not limitation, a partial view of an example of a lift pin actuator in accordance with the present disclosure is shown in FIG. 1 and is designated generally by reference character 100. Other examples of lift pin actuators, actuator arrangements and semiconductor processing systems including lift pin actuators, and methods of making lift pin actuators and actuator arrangements in accordance with the present disclosure, or aspects thereof, are provided in FIGS. 2-20, as will be described. The systems and methods of the present disclosure may be used to actuate lift pins in semiconductor processing systems, such as in single wafer cold wall chamber arrangements having cross flow architectures employed to deposit silicon-containing material layers onto substrates, though the present disclosure is not limited to any particular chamber arrangement or to semiconductor processing systems employed to deposit material layers onto substrates in general.

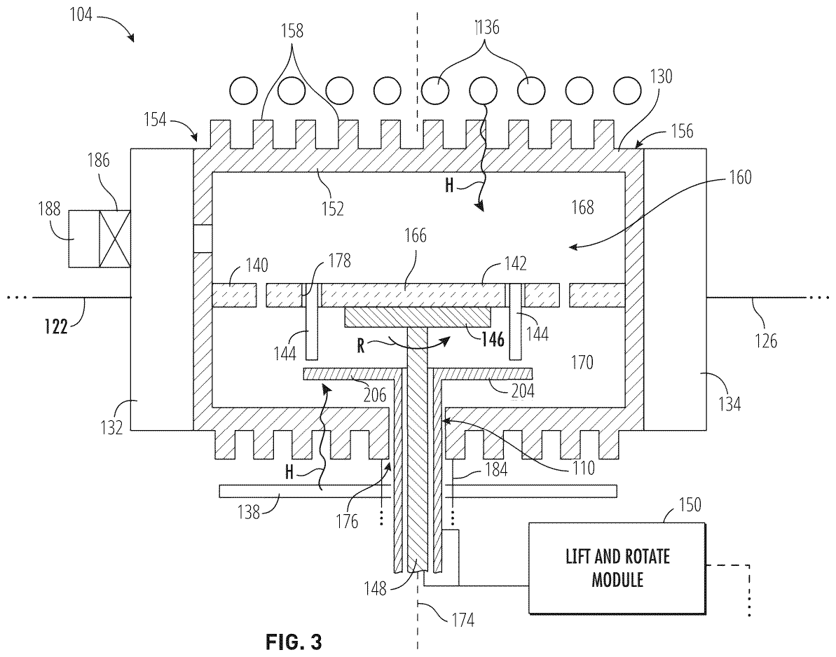

Referring to FIG. 1, a semiconductor processing system 100 is shown. The semiconductor processing system 100 generally includes a process fluid source 102, a chamber arrangement 104, an exhaust source 106, and a controller 108. The process fluid source 102 is configured to communicate a process fluid 10 to the chamber arrangement 104. The chamber arrangement 104 in turn couples the process fluid source 102 to the exhaust source 106, includes a lift pin actuator 200 and an actuator tube member 300, and may be configured to communicate the process fluid 10 to a substrate, e.g., a substrate 2 (shown in FIG. 3), seated in the chamber arrangement 104 using the lift pin actuator 200. The exhaust source 106 couples the chamber arrangement 104 to an external environment 12 outside of the semiconductor processing system 100, for example through a vacuum pump and/or an abatement device such as a scrubber, and is configured to communicate a flow of residual process fluid and/or reaction products to the external environment 12. It is contemplated that the controller 108 be operably coupled to one or more of the process fluid source 102, the chamber arrangement 104, and the exhaust source 106 by a wired or wireless link 112, for example to operate the lift pin actuator 200 and/or control processing of substrates within the chamber arrangement 104.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN), and silicon carbide (SiC). A substrate may include a pattern or may be unpatterned, such as a so-called blanket-type substrate. As examples, substrates in the form of a powder may have applications for pharmaceutical manufacturing.

A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrates are mounted.

With reference to FIG. 2, the semiconductor processing system 100 is shown according to an example of the present disclosure. In the illustrated example the semiconductor processing system 100 is configured to deposit a silicon-containing material layer 4 onto the substrate 2 using an epitaxial technique using the process fluid source 102 and includes a silicon-containing material layer precursor source 114, a dopant-containing material layer precursor source 116, an etchant source 118, and a carrier/diluent fluid source 120. The silicon-containing material layer precursor source 114 includes a silicon-containing material layer precursor 16 and is coupled to the chamber arrangement 104 by a process fluid supply conduit 122. The silicon-containing material layer precursor source 114 is further configured to communicate a flow of the silicon-containing material layer precursor 16 to the chamber arrangement 104 and in this respect may be coupled to the chamber arrangement 104 through one or more mass flow control devices, e.g., a mass flow controller (MFC) device, operatively associated with the controller 108.

In certain examples the silicon-containing material layer precursor 16 may include a non-halogenated silicon-containing material layer precursor. Non-limiting examples of suitable non-halogenated silicon-containing material layer precursors include silane (SiH₄), disilane (Si₂H₆), trisilane(Si₃H₈), and tetrasilane (Si₄H₁₀). In accordance with certain examples, the silicon-containing material layer precursor 16 may include a halogenated silicon-containing material layer precursor. Non-limiting examples of suitable halogenated silicon-containing material layer precursors include chlorosilane (SiH₃Cl), dichlorosilane (H₂SiCl₂), and trichlorosilane (SiHCl₃). It is contemplated that the silicon-containing material layer precursor source 114 may include two or more of the aforementioned silicon-containing material layer precursors and be configured to communicate the two or more silicon-containing material layer precursors to the chamber arrangement 104. It is also contemplated that the silicon-containing material layer precursor source 114 may cooperate with a metal-containing material layer precursor source 124 including a metal-containing material layer precursor 18 and configured to provide a flow of the metal-containing material layer precursor 18 to the chamber arrangement 104. Examples of suitable metal-containing material layer precursors include germanium (Ge) and gallium (Ga), for example as provided to the chamber arrangement 104 via flow of germane (GeH₄) and/or gallium trichloride (GaCl₃) from the metal-containing material layer precursor source 124.

The dopant-containing material layer precursor source 116 is similar to the silicon-containing material layer precursor source 114, additionally includes a dopant-containing material layer precursor 20 and is configured to communicate a flow of the dopant-containing material layer precursor 20 to the chamber arrangement 104. In certain examples the dopant-containing material layer precursor 20 may include a p-type dopant. Examples of suitable p-type dopants include boron (B) and indium (In). In accordance with certain examples, the dopant-containing material layer precursor 20 may include an n-type dopant. Examples of suitable n-type dopants include phosphorus (P) and arsenic (As). It is also contemplated that the dopant-containing material layer precursor source may include carbon (C) and remain within the scope of the present disclosure. As will be appreciated by those of skill in the art in view of the present disclosure, other dopants may be employed and remain within the scope of the present disclosure.

The etchant source 118 is similar to silicon-containing material layer precursor source 114, additionally includes an etchant 22, and is further configured to communicate the etchant 22 to the chamber arrangement 104. In certain examples the etchant 22 may include a chlorine-containing etchant. For example, the etchant 22 may include hydrochloric (HCl) acid and/or chlorine (Cl₂) gas. In accordance with certain examples, the etchant 22 may include a fluorine-containing etchant. Examples of suitable fluorine-containing etchants include hydrofluoric (HF) acid and fluorine (F₂) gas. It is contemplated that the etchant source 118 may be configured to provide the etchant 22 to the chamber arrangement 104 intermixed with the silicon-containing material layer precursor 16 and/or independent of the silicon-containing material layer precursor 16, for example as a cleaning or purge fluid. As will be appreciated by those of skill in view of the present disclosure, other etchants may be included in the etchant source 118 and remain within the scope of the present disclosure.

The carrier/diluent fluid source 120 is similar to the silicon-containing material layer precursor source 114, additionally includes a carrier/diluent fluid 24, and is further configured to provide a flow of the carrier/diluent fluid 24 to the chamber arrangement 104. In certain examples the carrier/diluent fluid source 120 may be configured to provide the carrier/diluent fluid 24 to the chamber arrangement 104 intermixed with one or more of the silicon-containing material layer precursor 16, the metal-containing material layer precursor 18, the dopant-containing material layer precursor 20, and the etchant 22. In accordance with certain examples, the carrier/diluent fluid source 120 may be configured to provide the carrier/diluent fluid 24 to chamber arrangement 104 independently of one or more of the aforementioned fluids. Examples of suitable carrier/diluent fluids include hydrogen (H₂) gas and inert gases like nitrogen (N₂) gas, argon (Ar) gas, and mixtures including one or more of the aforementioned fluids.

The exhaust source 106 is coupled to the chamber arrangement 104 by a process fluid exhaust conduit 126 and is configured to maintain a predetermined pressure within the chamber arrangement 104. In certain examples the exhaust source 106 may be configured to maintain a pressure within the chamber arrangement 104 within a pressure range suitable for atmospheric pressure processing, such as between about 760 Torr and about 710 Torr. In accordance with certain examples, the exhaust source 106 may be configured to maintain a pressure within the chamber arrangement 104 within a pressure range suitable for reduced pressure processing, for example between about 710 Torr and about 0.1 Torr. As used herein the term processing may refer to processing operations during which material layers are deposited onto substrates, processing operations during which material is removed from a substrate, and processing operations during which material layers are deposited and material removed from a substrate seated within the chamber arrangement 104.

With reference to FIG. 3, the chamber arrangement 104 is shown according to an example of the disclosure. In the illustrated example the chamber arrangement 104 has a single-wafer crossflow architecture 128 and includes a chamber body 130, an injection flange 132, and an exhaust flange 134. The chamber arrangement 104 also includes an upper heater element array 136, a lower heater element array 138, and a divider 140. As shown and described herein the chamber arrangement 104 also includes a substrate support 142 with a plurality of lift pins 144 slidably received therein, a support member 146, a shaft member 148, and a lift and rotate module 150. Although shown and described herein as having a specific arrangement and including certain elements, it is to be understood and appreciated that the chamber arrangement 104 may have a different arrangement, as well as include additional elements or exclude elements shown and described herein and remain within the scope of the present disclosure.

The chamber body 130 is formed from a ceramic material 152, e.g., a ceramic material transparent to electromagnetic radiation in an infrared waveband and has an injection end 154 and a longitudinally opposite exhaust end 156. Examples of suitable ceramic materials include quartz, fused silica, and sapphire. In certain examples the chamber body 130 may have a substantially planar upper wall and/or a substantially planar lower wall. In such examples the chamber body 130 may further have a plurality of external ribs 158 extending laterally about the exterior of the chamber body 130 and longitudinally spaced apart from one another between the injection end 154 and the exhaust end 156 of the chamber body 130. In accordance with certain examples, either (or both) the upper wall and the lower wall of the chamber body 130 may be arcuate or dome-like in shape and remain within the scope of the present disclosure.

The injection flange 132 abuts the injection end 154 of the chamber body 130 and fluidly couples the process fluid source 102 (shown in FIG. 1) to an interior 160 of the chamber body 130. In this respect the process fluid supply conduit 122 may connect the process fluid source 102 to the injection flange 132 to communicate the process fluid 10 into the interior 160 of the chamber body 130. The exhaust flange 134 abuts the exhaust end 156 of the chamber body 130 and fluidly couples the interior 160 of the chamber body 130 to the exhaust source 106 (shown in FIG. 1). In this regard the process fluid exhaust conduit 126 may connect the exhaust flange 134 to the exhaust source 106 to communicate the residual process fluid and/or reaction products to the exhaust source 106. In certain examples, the injection flange 132 may be as shown and described in U.S. Pat. No. 11,053,591 to Ma et al., issued on Jul. 6, 2021, the contents of which is incorporated herein by reference in its entirety. In accordance with certain examples, the exhaust flange 134 may be as shown and described in U.S. Pat. No. 10,612,136 to Sreeram et al., issued on Apr. 7, 2020, the contents of which is incorporated herein by reference in its entirety.

The upper heater element array 136 is supported above the chamber body 130 and includes a plurality of upper heater elements 162. It is contemplated that the upper heater elements 162 be operably associated with the controller 108 (shown in FIG. 1) and configured to communicate heat H into the interior 160 of the chamber body 130. In certain examples the plurality of upper heater elements 162 may each include a linear filament, extend laterally across the upper wall of the chamber body 130, and are longitudinally spaced apart from one another between the injection end 154 and the exhaust end 156 of the chamber body 130. In accordance with certain examples, the plurality of upper heater elements 162 may extend longitudinally between the injection end 154 and the exhaust end 156 of the chamber body 130, the plurality of upper heater elements 162 laterally spaced apart from one another between laterally opposite side walls of the chamber body 130. The lower heater element array 138 may be similar to the upper heater element array 136 and additionally include a plurality of lower heater elements 164 each supported below the lower wall of the chamber body 130. In certain examples the plurality of lower heater elements may be substantially orthogonal relative to the plurality of upper heater elements 162. Although shown and described herein as including linear filament-type heater elements, it is to be understood and appreciated that either (or both) the upper heater element array 136 and the lower heater element array 138 may include bulk-type heater elements and remain within the scope of the present disclosure.

The divider 140 is formed from an opaque material 166 (e.g., a material opaque to electromagnetic radiation in an infrared waveband) and is supported within the interior 160 of the chamber body 130. It is contemplated that the divider 140 divide the interior 160 of the chamber body 130 into an upper chamber 168 and the lower chamber 170. It is also contemplated that the divider 140 defines a divider aperture 172 therethrough and that the divider aperture 172 fluidly couples the upper chamber 168 to the lower chamber 170. It is further contemplated that the substrate support 142 be arranged within the interior 160 of the chamber body 130 at least partially within the divider aperture 172 and be supported therein for rotation R about a rotation axis 174. In certain examples the opaque material 166 may include a bulk carbonaceous material, such as pyrolytic carbon or graphite with a ceramic coating. In accordance with certain examples, the opaque material 166 may include a bulk ceramic material, such as silicon carbide by way of example and not limitation. It is contemplated that the substrate support 142 may also be formed (at least in part) from the opaque material 166.

The support member 146 is arranged along the rotation axis 174 and within the lower chamber 170 of the chamber body 130 and is fixed relative to the substrate support 142. It is contemplated that the support member 146 be formed from a material transparent to electromagnetic radiation within an infrared waveband, for example the ceramic material 152. The shaft member 148 is also arranged along the rotation axis 174 and is additionally fixed in rotation relative to the support member 146 in rotation about the rotation axis 174. The shaft member 148 further extends through a passthrough 176 defined within the lower wall of the chamber body 130 and into the external environment outside of the chamber body 130, and operably couples the lift and rotate module 150 to the substrate support 142 to rotate the substrate support 142 via the shaft member 148 and the support member 146 about the rotation axis 174. In certain examples the shaft member 148 may be formed from a material transparent to electromagnetic radiation within an infrared waveband, such as the ceramic material 152.

The plurality of lift pins 144 are slidably received within the respective lift pin apertures 178 defined within the substrate support 142. It is contemplated that the plurality of lift pins 144 be configured to seat and unseat substrates, e.g., the substrate 2, from the substrate support 142 and in this respect are supported within the interior 160 of chamber body 130 at a location above a lift pin actuator 200 and an actuator tube member 300 relative to gravity. The lift pin actuator 200 is arranged along the rotation axis 174 within (at least in part) the lower chamber 170 of the chamber body 130, is seated on the actuator tube member 300, and is translatable along the rotation axis 174 between a retracted position 180 and an extended position 182 along the rotation axis 174. The actuator tube member 300 seats the lift pin actuator 200 thereon, extends through the passthrough 176 into the external environment outside of the chamber body 130.

It is contemplated that the actuator tube member 300 be supported for translation relative to the shaft member 148 along the rotation axis 174 to drive the lift pin actuator 200 between the retracted position 180, wherein the lift pin actuator 200 is proximate the lower wall of the chamber body 130 such that the lift pins dangle below the substrate support 142 within the lower chamber 170 of the chamber body 130, and the extended position 182, wherein the lift pin actuator 200 is proximate the substrate support 142 and in abutment with the plurality of lift pins 144 such that each of the plurality of lift pins 144 protrudes above the substrate support 142 and into the upper chamber 168 of the chamber body 130. Translation of the actuator tube member 300 and thereby the lift pin actuator 200 may be through operable association of the lift and rotate module 150. In certain examples either (or both) the lift pin actuator 200 and the actuator tube member 300 may be formed from (e.g., consist of or consist essentially of) a ceramic material, such as the ceramic material 152. In accordance with certain examples, an exterior surface of the shaft member 148 and an interior surface of the actuator tube member 300 may be radially spaced apart from one another to define an annular flow area therebetween. It is also contemplated that a tubulation member 184 may be fixed to the lower wall of the chamber body 130 and about the passthrough 176, the actuator tube member 300 and the shaft member 148 arranged at least partially in the tubulation member 184.

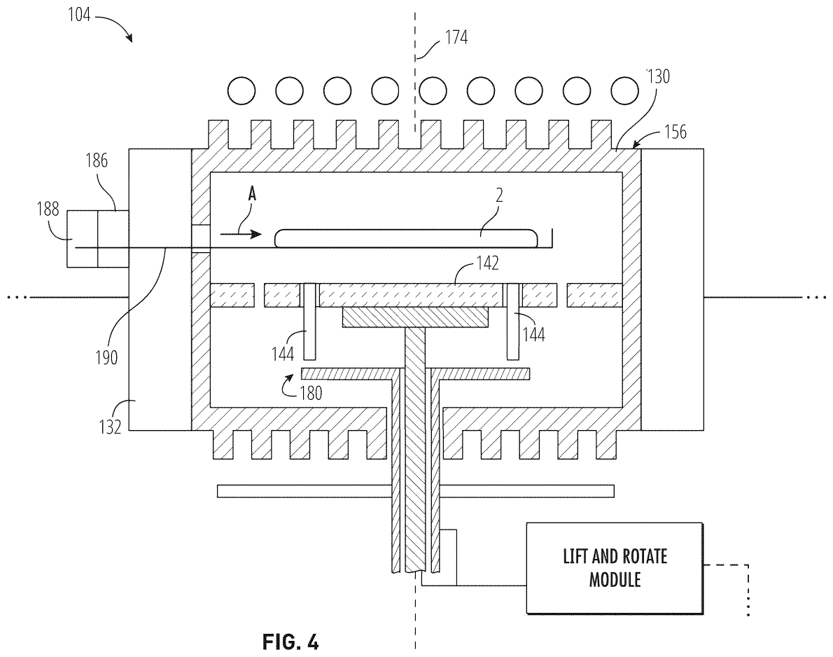

With reference to FIGS. 4-8, loading and seating of the substrate 2 within the chamber arrangement 104 prior to processing of the substrate 2, processing (e.g., deposition of the material layer 4) of the substrate 2, and unseating and unloading of the substrate 2 from the chamber arrangement 104 subsequent to processing are sequentially shown. As shown in FIG. 4, loading of the substrate 2 into the chamber arrangement 104 is accomplished by opening a gate valve 186 connected to the injection flange 132 of the chamber arrangement 104, advancing an end effector 190 carrying the substrate 2 into the upper chamber 168 of the chamber body 130 using a substrate transfer robot 188 coupled to the chamber body 130. It is contemplated that the substrate transfer robot 188 advance A the end effector 190 longitudinally into the upper chamber 168 and toward the exhaust end 156 of the chamber body 130 until the substrate 2 is centered about the rotation axis 174 at a location above the substrate support 142 and the plurality of lift pins 144. So positioned, the substrate may be seated on the substrate support 142.

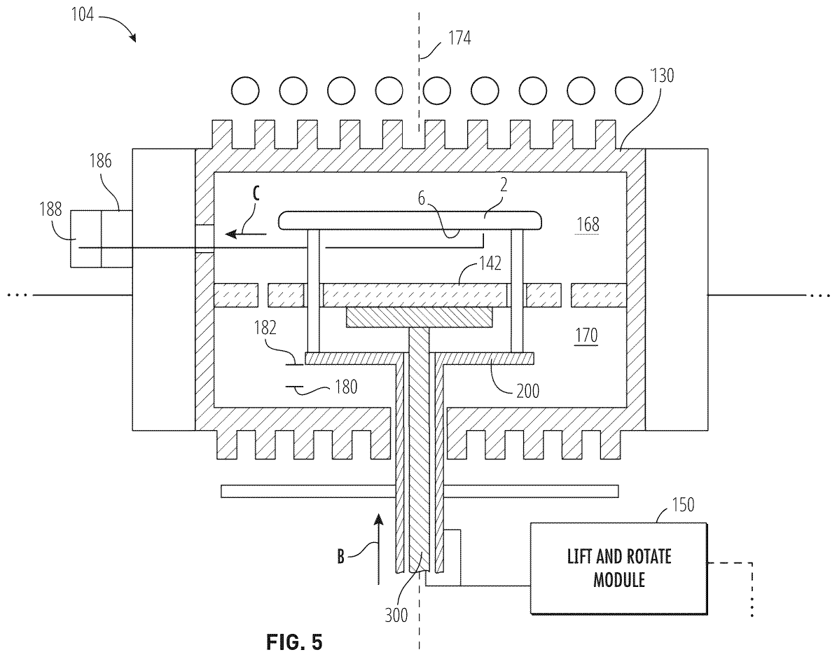

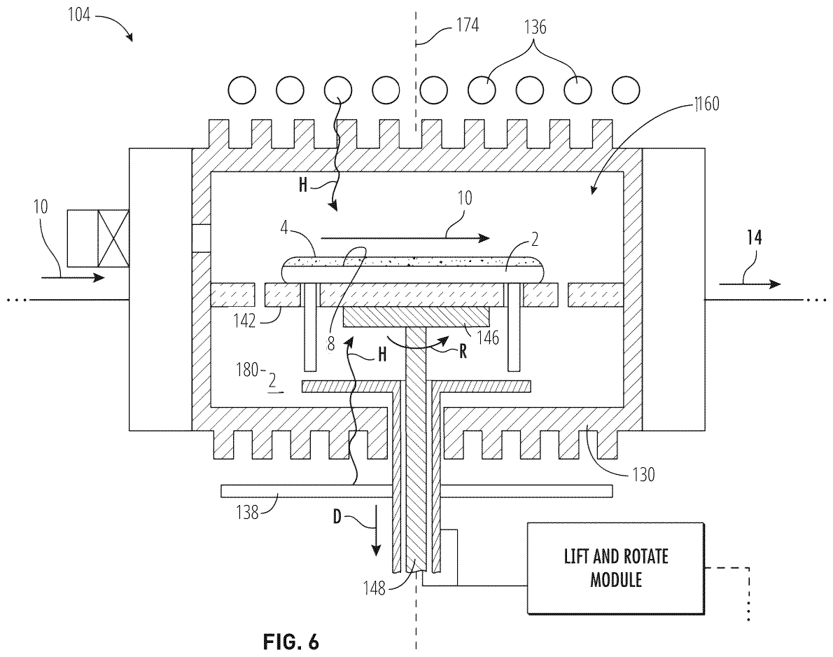

As shown in FIG. 5, seating of the substrate 2 on the substrate support 142 is accomplished by driving B the lift pin actuator 200 from the retracted position 180 to the extended position 182. In this respect it is contemplated that the lift and rotate module 150 drive the actuator tube member 300 (and thereby the lift pin actuator 200 seated thereon) axially along the rotation axis 174 within the lower chamber 170 of the chamber body 130 upwards, in a direction toward the substrate support 142. As the lift pin actuator 200 translates upward within the lower chamber 170 the lift pin actuator 200 comes into contact with an end of the plurality of lift pins 144 dangling into the lower chamber 170 from the substrate support 142. Further translation thereafter drives the plurality of lift pins 144 through the substrate support 142 such that the plurality of lift pins 144 protrude above the substrate support 142, the plurality of lift pins 144 coming into contact with an underside of the substrate 2. As the plurality of lift pins 144 are in contact with the underside 6 of the substrate 2 further translation of the lift pin actuator 200 causes the substrate 2 to transfer from the end effector 190 to the plurality of lift pins 144 as the plurality of lift pins 144 approach the extended position 182. The substrate transfer robot 188 may thereafter withdraw C the end effector 190 from the upper chamber 168 of the chamber body 130, the gate valve 186 closed, and the lift pin actuator 200 translated downward D (shown in FIG. 6) within the lower chamber 170 in a direction axially opposite the substrate support 142 toward the retracted position 180. As the lift pin actuator 200 translates downward, the plurality of lift pins 144 translate downward through the substrate support 142 by operation of gravity, the substrate 2 thereby transferring to the substrate support 142 as the plurality of lift pins 144 approach the retracted position 180. The substrate 2 may be processed within the chamber arrangement 104 (e.g., within the chamber body 130) to deposit the material layer 4 onto the substrate 2.

As shown in FIG. 6, processing of the substrate 2 may be accomplished by heating the substrate 2 to a predetermined material layer deposition temperature, for example to a temperature that is between about 200 degrees Celsius and about 1200 degrees Celsius, using either (or both) the upper heater element array 136 and the lower heater element array 138. Processing of the substrate 2 may further be accomplished by establishing- and thereafter maintaining-a predetermined material layer deposition pressure within the interior 160 of the chamber body 130, for example, using a vacuum pump included in the exhaust source 106 (shown in FIG. 1). In this respect it is contemplated that pressure within the interior 160 of the chamber body 130 be maintained within a range that is between about 0.1 Torr and 760 Torr, for example between about 760 Torr and about 720 Torr (for deposition of the material layer 4 using an atmospheric technique) or between about 720 Torr and about 0.1 Torr (for deposition of the material layer 4 using a reduced pressure technique). The substrate support 142 with the substrate 2 seated thereon may further be rotated about the rotation axis 174 by the lift and rotate module 150 using rotation R communicated to the substrate support 142 through the shaft member 148 and the support member 146, for example at a predetermined material layer deposition rotational speed.

It is contemplated that an upper surface 8 of the substrate 2 be exposed to the process fluid 10 while the substrate is maintained at the predetermined deposition temperature and the interior 160 of the chamber body 130 maintained at the predetermined deposition pressure. It is also contemplated that the process fluid 10 in turn include the silicon-containing material layer precursor 16 (shown in FIG. 2) and one or more of the metal-containing material layer precursor 18 (shown in FIG. 2), the dopant-containing material layer precursor 20 (shown in FIG. 2), the etchant 22 (shown in FIG. 2), and the carrier/diluent fluid 24 (shown in FIG. 2), the material layer 4 thereby being a silicon-containing material layer, the material layer 4 further being epitaxial with the substrate 2 in certain examples of the present disclosure. It is further contemplated that the flow of the process fluid 10 cease once the material layer 4 develops one or more predetermined properties (e.g., thickness and/or resistivity), rotation of the substrate support 142 about the rotation axis 174 cease, and that heating of the substrate and pressure within the interior 160 of the chamber body 130 be adjusted such that the substrate 2 with the material layer 4 deposited thereon may be unseated from the substrate support 142 and unloaded from the chamber body 130.

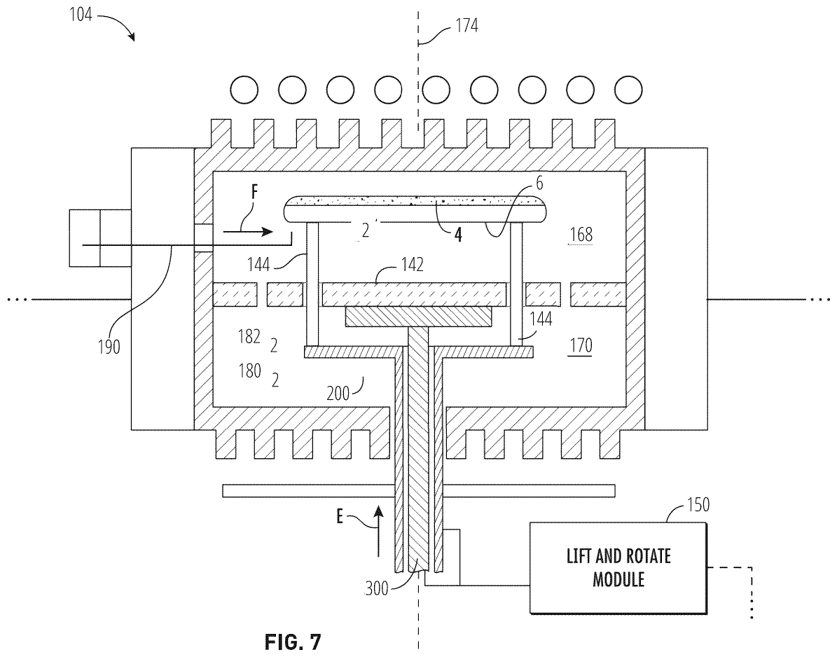

As shown in FIG. 7, unseating of the substrate 2 from the substrate support 142 may be accomplished by once again translating the lift pin actuator 200 from the retracted position 180 to the extended position 182. In this respect it is contemplated that the lift and rotate module 150 again drive E the actuator tube member 300 (and thereby the lift pin actuator 200 seated thereon) axially along the rotation axis 174 within the lower chamber 170 toward the substrate support 142. As the lift pin actuator 200 translates upward within the lower chamber 170 the lift pin actuator 200 comes into contact with an end of the plurality of lift pins 144 dangling into the lower chamber 170 from the substrate support 142. Further translation of the lift pin actuator 200 thereafter drives the plurality of lift pins 144 through the substrate support 142 such that the plurality of lift pins 144 come into contact with the underside 6 of the substrate 2. Continuing translation of the lift pin actuator 200 along the rotation axis 174 causes the plurality of lift pins 144 to protrude from the substrate support 142 into the upper chamber 168 of the chamber body 130, unseating the substrate 2 from the substrate support 142, the substrate 2 ultimately supported above the substrate support 142 at a position where the end effector 190 may again be advanced F into the upper chamber 168 to a position axially between the substrate 2 and the substrate support 142 once the lift pin actuator 200 reaches the extended position 182. So positioned, the substrate may be unloaded from the chamber arrangement 104.

Unloading of the substrate 2 with the material layer 4 deposited thereon may be accomplished by again opening the gate valve 186. Once the gate valve 186 is open the substrate transfer robot 188 may again advance the end effector 190 longitudinally into the chamber body 130 toward the exhaust flange 134. In this respect it is contemplated that the end effector 190 be positioned such that the end effector 190 is below the substrate 2, axially spaced apart from both the underside 6 of the substrate 2 and the substrate support 142, and registered to the substrate 2 such that movement of the lift pin actuator from the extended position 182 toward the retracted position 180 causes the substrate 2 to transfer to the end effector 190. Once the end effector 190 is positioned the lift and rotate module 150 may translate the actuator tube member 300 (and the lift pin actuator 200 seated thereon) downward along the rotation axis 174. Downward translation of the actuator tube member 300 translates the lift pin actuator 200 from the extended position 182, the plurality of lift pins 144 sliding downwards through the substrate support 142 by operation of gravity, and the substrate 2 transferring from the plurality of lift pins 144 to the end effector 190 as the plurality of lift pins 144 seat in the substrate support 142 and dangle therefrom into the lower chamber 170 of the chamber body 130. The substrate transfer robot 188 may then withdraw the end effector 190 carrying the substrate 2 with the material layer 4 deposited thereon from the upper chamber 168, the gate valve 186 may be closed, and the chamber arrangement 104 prepared for processing a subsequent substrate.

One challenge to operation of chamber arrangements with lift pin actuators is that the lift pin actuator may need to be oversized in relation to a size otherwise preferable due to tendency of the lift pin actuator to shadow the underside of the substrate support. For example, the lift pin actuator may have a circumferential extent greater than otherwise desirable due to error in registration of the lift pins relative to the lift pin actuator at the end of deposition. The lift pin actuator may further have a greater radial extent than otherwise desirable due to a tendency of the lift pin actuator to pitch and/or roll about the end of the actuator tube member upon engagement of the lift pins. The tendency of the lift pin actuator to pitch and/or roll may be exacerbated in deposition processes wherein the substrate support is precoated, or the lift pins themselves are prone to accretion during deposition, such precoats and accretions increasing the force required to drive the lift pins during movement in an asymmetric way. To limit shading of the underside of the substrate support 142 and/or limit lift pin actuator displacement in processes employing precoats and/or which may be subject to accretion formation within the chamber body 130 on components such as the plurality of lift pins 144, the lift pin actuator 200 and the actuator tube member 300 are provided.

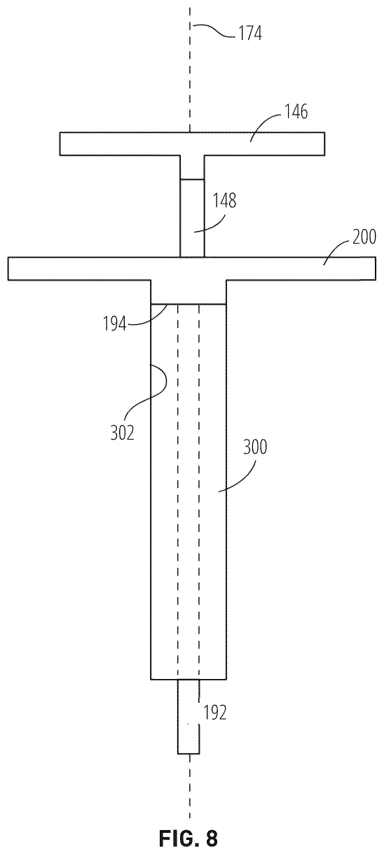

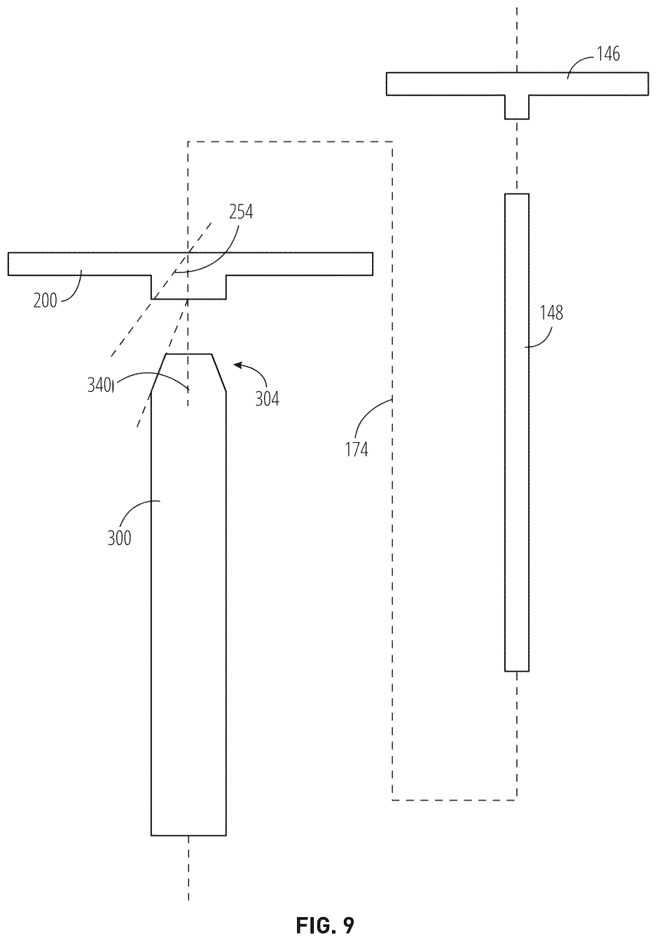

With reference to FIGS. 8 and 9, a portion of the chamber arrangement 104 is shown including the lift pin actuator 200 and the actuator tube member 300. As shown in FIG. 9, the lift pin actuator 200 is arranged along the rotation axis 174, extends about the rotation axis 174, and is axially offset from the support member 146 along the rotation axis 174. The actuator tube member 300 is also arranged along the rotation axis 174, extends about the shaft member 148, and seats the lift pin actuator 200 thereon. The shaft member 148 protrudes axially from the lift pin actuator 200 in a direction axially opposite the actuator tube member 300, seats thereon the support member 146, and is radially spaced apart from an interior surface 202 of the actuator tube member 300 such that an exterior surface 192 and the interior surface 202 of the actuator tube member 300 define a radial gap 194 therebetween. It is contemplated that a fluid source, e.g., the carrier/diluent fluid source 120 (shown in FIG. 2), may be connected to the actuator tube member 300 such that the actuator tube member 300 fluidly couples the fluid source to the lower chamber 170 (shown in FIG. 3) of the chamber body 130 (shown in FIG. 3).

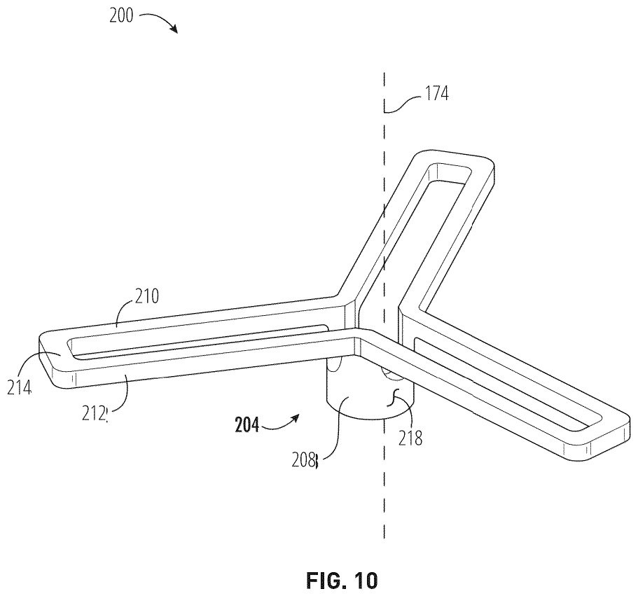

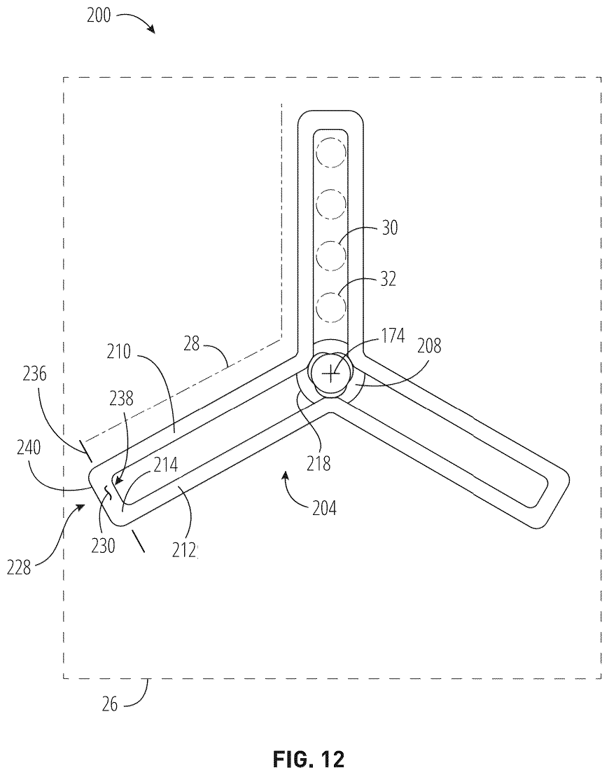

With reference to FIGS. 10-14, the lift pin actuator 200 is shown according to an example of the present disclosure. As shown in FIG. 10, the lift pin actuator 200 generally includes an actuator body 204. The actuator body 204 is configured for translation along the rotation axis 174 within the lower chamber 170 (shown in FIG. 3) of the chamber body 130 (shown in FIG. 3). The actuator body 204 is further formed from a ceramic material 206 (shown in FIG. 3), such as a ceramic material transparent to electromagnetic radiation within an infrared waveband and may consist of or consist essentially of the ceramic material 206. As will be appreciated by those of skill in the art in view of the present disclosure, forming the actuator body 204 from a ceramic material may limit variation within the material layer 4 (shown in FIG. 3) deposited onto the substrate 2 (shown in FIG. 3), for example by limiting cross-substrate temperature non-uniformity during deposition of the material layer 4 onto the substrate 2 due to shading of the underside of the substrate support 142 (shown in FIG. 3) to electromagnetic radiation communicated into the interior 160 (shown in FIG. 3) of the chamber body 130 (shown in FIG. 3) by the lower heater element array 138 (shown in FIG. 3) by the lift pin actuator 200. In certain examples of the present disclosure the ceramic material 206 may be quartz. It is also contemplated that the ceramic material 206 may be fused silica or sapphire and remain within the scope of the present disclosure. In accordance with certain examples, the lift pin actuator 200 may be formed from a singular workpiece 26 (shown in FIG. 12) (e.g., a singular ceramic workpiece body) using a subtractive manufacturing technique. For example, the lift pin actuator 200 may be formed using two or more of a cutting or sawing operation 28, a boring or drilling operation 30, and a milling operation 32 by way of non-limiting example. As will be appreciated by those of skill in the art in view of the present disclosure, using two or more subtractive manufacturing techniques may reduce the time required to manufacture the lift pin actuator 200, for example due to relatively high material removal rates of cutting or sawing as well as boring or drilling relative to milling, limiting cost of the semiconductor processing system 100 (shown in FIG. 1) including the lift pin actuator 200.

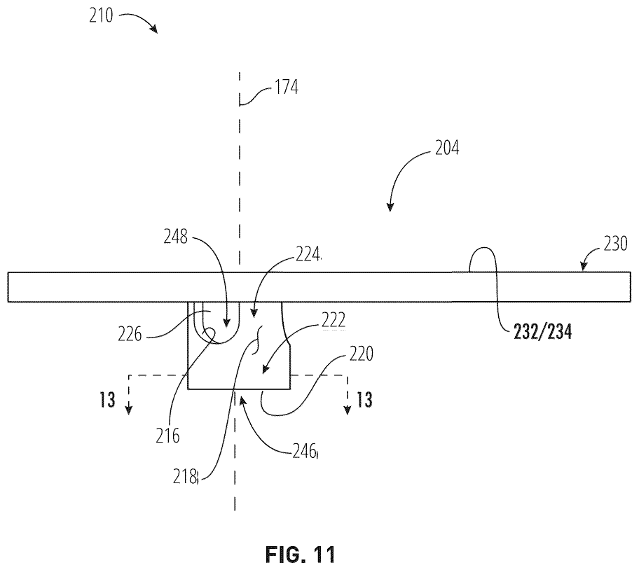

It is contemplated that the lift pin actuator 200 be configured to drive the plurality of lift pins 144 (shown in FIG. 3) and in this respect the actuator body 204 has a hub portion 208, a first arm portion 210 and a second arm portion 212, and a pad portion 214. The hub portion 208 extends about the rotation axis 174 and has an upper surface 216 (shown in FIG. 11), a radial exterior surface 218, and a lower surface 220 (shown in FIG. 11). It is contemplated that the upper surface 216 be angled relative to the rotation axis 174 and in this respect the upper surface 216 may be orthogonal relative to the rotation axis 174. The radial exterior surface 218 extends axially from the upper surface 216 along the rotation axis 174 toward the lower surface 220 and about the rotation axis 174, and axially separates the lower surface 220 from the upper surface 216 of the hub portion 208 of the actuator body 204. The lower surface 220 is angled relative to the rotation axis 174 and may be substantially orthogonal relative to the rotation axis 174. In certain examples the lower surface 220 may be wider than the upper surface 216, the hub portion 208 having a generally frustoconical shape in such examples. It is also contemplated that the hub portion 208 may be cylindrical in shape and remain within the scope of the present disclosure.

As shown in FIG. 11, it is contemplated that the hub portion 208 of the actuator body 204 may be castellated. In this respect the hub portion 208 has an annular segment 222 and a plurality of merlon segments 224. The annular segment 222 extends axially along the rotation axis 174 and about the rotation axis 174. The annular segment 222 further extends axially between the lower surface 220 and the upper surface 216 of the hub portion 208 of the actuator body 204. The plurality of merlon segments 224 extend axially from the annular segment 222 of the hub portion 208 of the actuator body 204, are distributed about the rotation axis 174, and couple the first arm portion 210 (shown in FIG. 10) and the second arm portion 212 (shown in FIG. 10) to the annular segment 222 of the hub portion 208 of the actuator body 204. It is further contemplated that the plurality of merlon segments 224 axially separate the first arm portion 210 and the second arm portion 212 from the annular segment 222 of the hub portion 208 of the actuator body 204, and define between one another a plurality of crenels 226. The plurality of crenels 226 extend axially between the annular segment 222 and the arm portions of the hub portion 208 (e.g., the first arm portion 210 and the second arm portion 212), and each separates circumferentially adjacent merlon segments 224 from one another. In the illustrated example the hub portion 208 has three (3) merlon segments 224 circumferentially separated by three (3) crenels 226. As will be appreciated by those of skill in the art in view of the present disclosure, the hub portion 208 may have fewer or additional merlon segments and crenels in other examples and remain within the scope of the present disclosure.

As shown in FIG. 12, the first arm portion 210 and the second arm portion 212 extend outward (e.g., chordwise) from the hub portion 208 and in a direction opposite the rotation axis 174. The second arm portion 212 may further be substantially parallel to the first arm portion 210 and may be orthogonal relative to the rotation axis 174. In certain examples, the first arm portion 210 and the second arm portion 212 may be substantially orthogonal relative to the radial exterior surface 218 of the hub portion 208 of the actuator body 204. In accordance with certain examples, the first arm portion 210 may axially overlap a first of the plurality of merlon segments 224 (shown in FIG. 11) and the second arm portion 212 may axially overlap a second of the plurality of merlon segments 224, a singular one of the plurality of crenels 226 (shown in FIG. 11) in turn circumferentially separating the second arm portion 212 from the first arm portion 210 of the actuator body 204.

It is contemplated that the first arm portion 210 and the second arm portion 212 form a first arm pair 228. The first arm pair 228 may be one of a plurality of arm pairs extending outward from the hub portion and distributed circumferentially about the rotation axis 174. The plurality of arm pairs may in turn be distributed circumferentially about the rotation axis 174, for example symmetrically such that each arm pair is separated from the adjacent arm pair by a common angular offset about the rotation axis 174. In the illustrated example the first arm pair 228 is one of three (3) arm pairs distributed circumferentially about the rotation axis 174 and the hub portion 208 of the actuator body 204. As will be appreciated by those of skill in the art in view of the present disclosure, the actuator body 204 may have fewer or additional arm pairs than shown and described herein and remain within the scope of the present disclosure.

The pad portion 214 of the actuator body 204 is radially separated from the hub portion 208 of the actuator body 204. The pad portion 214 further couples the second arm portion 212 to the first arm portion 210 of the actuator body 204 and has an engagement surface 230. The engagement surface 230 is configured to engage bottom ends of the plurality of lift pins 144 (shown in FIG. 3) and in this respect may be substantially planar. In further respect, it is contemplated that the engagement surface 230 be substantially orthogonal relative to the rotation axis 174. In certain examples, the engagement surface 230 may be coplanar with a first arm portion upper surface 232 (shown in FIG. 11) and a second arm portion upper surface 234 (shown in FIG. 11). In accordance with certain examples, the pad portion 214 may define (e.g., trace) an arcuate segment 236 extending circumferentially about the rotation axis 174. It is contemplated that the pad portion 214 may be bounded by a radially inner pad surface 238 and a radially outer pad surface 240, the radially inner pad surface 238 extending between the first arm portion 210 and the second arm portion 212, the radially outer pad surface 240 extending in parallel with the radially inner pad surface 238 and circumferentially spanning both the first arm portion 210 and the second arm portion 212 of the actuator body 204. In the illustrated example the pad portion 214 is one of three (3) pad portions distributed circumferentially about the rotation axis 174. As will be appreciated by those of skill in the art in view of the present disclosure, the actuator body 204 may include fewer or additional pad portions than shown and described herein and remain within the scope of the present disclosure.

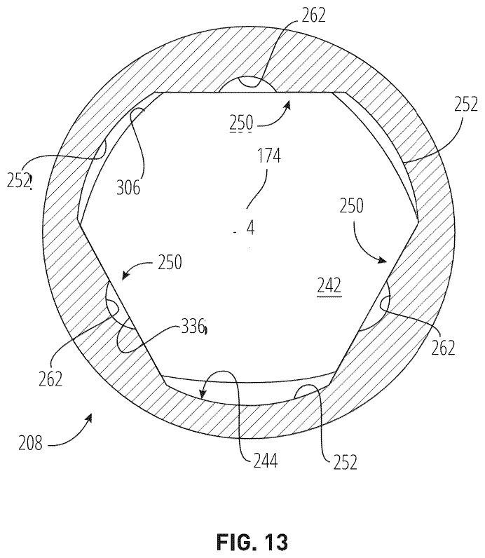

As shown in FIG. 13, it is contemplated that the hub portion 208 of the actuator body 204 be configured for seating onto the actuator tube member 300 (shown in FIG. 3). In this respect the hub portion 208 defines a seating socket 242 within an interior of the hub portion 208 of the actuator body 204. The seating socket 242 is bounded by an interior surface 244 of the hub portion 208, corresponds geometrically to a seat end 304 (shown in FIG. 9) of the actuator tube member 300, and is coupled to the external environment outside of the hub portion 208 by a seating aperture 246 (shown in FIG. 11) defined within the lower surface 220 (shown in FIG. 11) of the hub portion 208, and an upper surface aperture 248 (shown in FIG. 11) defined within the upper surface 216 (shown in FIG. 11) of the hub portion 208 of the actuator body 204. It is contemplated that the interior surface 244 of the hub portion 208 bounding the seating socket 242 define a plurality of planar faces 250. It is also contemplated that the interior surface 244 of the hub portion 208 of the actuator body 204 may define a plurality of arcuate faces 252 within the seating socket 242, and that the interior surface 244 couple the upper surface aperture 248 defined in the upper surface 216 to the seating aperture 246 defined in the lower surface 220.

The plurality of planar faces 250 are distributed circumferentially about the rotation axis 174. The plurality of planar faces 250 are further angled relative to the rotation axis 174, each of the plurality of planar faces 250 separated at greater distances from the rotation axis 174 proximate the lower surface 220 of the hub portion 208 than proximate the upper surface 216 of the hub portion 208 of the actuator body 204. In this respect it is contemplated that each of the plurality of planar faces 250 be angled relative to the rotation axis 174 (and/or relative to at least one of the upper surface 216 (shown in FIG. 11) and the lower surface 220 (shown in FIG. 11) of the hub portion 208) at a common planar face angle 254. The common planar face angle 254 may be an oblique angle. In certain examples, the common planar face angle 254 may be between about 5 degrees and 45 degrees, or between about 5 degrees and about 30 degrees, between about 5 degrees and about 15 degrees, or even between about 5 degrees and about 10 degrees. Advantageously, common planar face angles within these angular ranges may limit (or prevent entirely) tendency of the lift pin actuator 200 to fuse to the actuator tube member 300 (shown in FIG. 1), for example due to cyclic heating and cooling of the actuator arrangement 110 (shown in FIG. 3) due to sequential processing of substrates within the semiconductor processing system 100, simplifying maintenance of the semiconductor processing system 100 in examples where the lift pin actuator 200 may require periodic removal from the actuator tube member 300 during service events. In the illustrated example the interior surface 244 of the hub portion 208 has three (3) planar surfaces. As will be appreciated by those of skill in the art in view of the present disclosure, the lift pin actuator 200 may have fewer or additional planar faces in other examples and remain within the scope of the present disclosure.

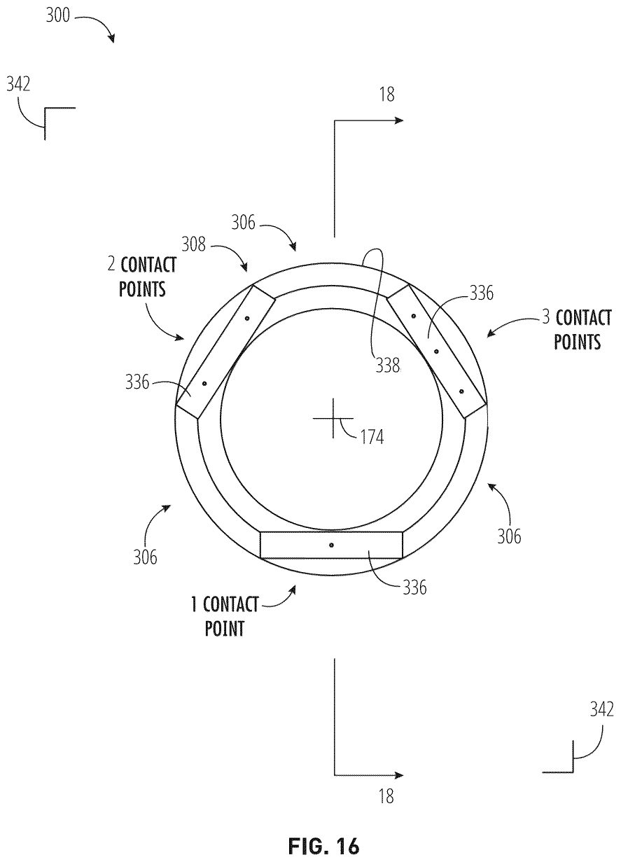

In certain examples one or more of the plurality of planar faces 250 may be bounded by an arcuate periphery 256. The arcuate periphery 256 may have a base 258, proximate the lower surface 220 of the hub portion 208 of the actuator body 204, and an open end 260 proximate the upper surface aperture 248 (shown in FIG. 11) defined within the upper surface 216 of the hub portion 208 of the actuator body 204. In accordance with certain examples, one or more of the plurality of planar faces 250 may have a relief channel 262 defined within the respective planar face 250. The relief channel 262 may extend from the open end 260 of the arcuate periphery 256 toward a location intermediate the open end 260 and the base 258 of the arcuate periphery 256. Advantageously, definition of the relief channel 262 within one or more of the plurality of planar faces 250 can promote stability of the lift pin actuator 200 on the actuator tube member 300 (shown in FIG. 3), for example by spreading contact points between the planar face 250 having the relief channel 262 and an abutting one of the plurality of planar facets 336 (shown in FIG. 16) defined on the seat end 304 (shown in FIG. 9) of the actuator tube member 300. As shown and described herein each of the plurality of planar faces 250 defines a singular relief channel 262 therein. As will be appreciated by those of skill in the art in view of the present disclosure, the plurality of planar faces 250 may have fewer or additional relief channels defined therein than shown and described herein and remain within the scope of the present disclosure.

With continuing reference to FIG. 13, the plurality of arcuate faces 252 defined by the interior surface 244 of the hub portion 208 are distributed circumferentially about the rotation axis 174. It is contemplated that individual arcuate faces of the plurality of arcuate faces 252 separate circumferentially adjacent ones of the plurality of planar faces 250, and that circumferentially adjacent ones of the plurality of arcuate faces 252 are separated by intermediate ones of the plurality of planar faces 250. In certain examples the plurality of arcuate faces 252 may be substantially parallel to the rotation axis 174. In accordance with certain examples, each of the plurality of arcuate faces 252 may be overcut relative to corresponding arcuate facets 306 defined on the seat end 304 (shown in FIG. 9) of the actuator tube member 300 (shown in FIG. 3), the respective arcuate face 252 and arcuate facet 306 defining a radial clearance therebetween. Advantageously, overcutting the plurality of arcuate faces 252 relative to the plurality of arcuate facets 306 ensures that the plurality of planar faces 250 locate the lift pin actuator 200 on the seat end 304 of the actuator tube member 300, promoting stability of the lift pin actuator 200 on the actuator tube member 300. As shown and described herein the interior surface 244 of the hub portion 208 has three (3) arcuate faces. As will be appreciated by those of skill in the art in view of the present disclosure, the lift pin actuator 200 (shown in FIG. 3) may have fewer or additional arcuate faces in other examples and remain within the scope of the present disclosure.

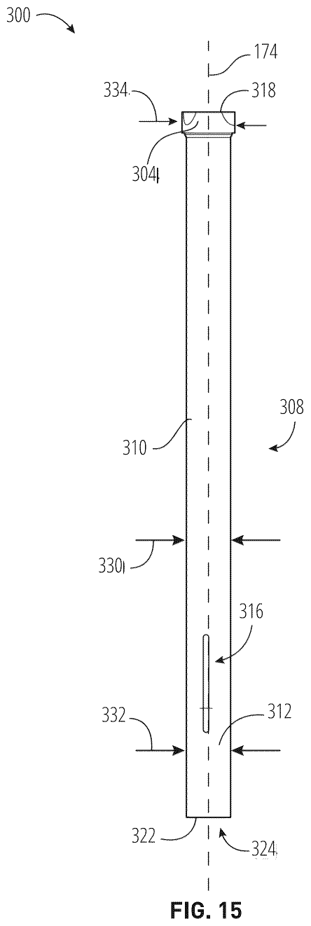

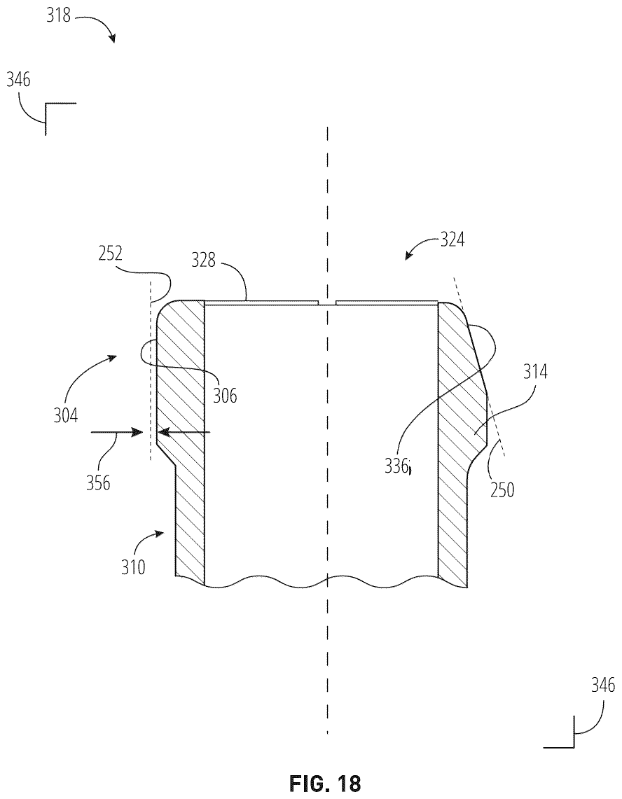

With reference to FIGS. 15-18, the actuator tube member 300 is shown according to an example of the disclosure. Referring to FIG. 15, the actuator tube member 300 is configured and adapted to seat thereon the lift pin actuator 200 (shown in FIG. 1) and in this respect includes a tube member body 308. It is contemplated that the tube member body 308 be arranged along the rotation axis 174 and extend about the rotation axis 174. It is also contemplated that the tube member body 308 have an actuation end 310 coupled to the seat end 304 by an intermediate segment 312, and that the tube member body 308 be formed from a ceramic material 314 (shown in FIG. 18). In certain examples, the ceramic material 314 may be transparent to electromagnetic radiation within an infrared waveband. Examples of suitable ceramic materials include fused silica, quartz, and sapphire. In accordance with certain examples, the tube member body 308 may consist of or consist essentially of the ceramic material 314.

The actuation end 310 of the tube member body 308 is configured for engagement to an actuation device, for example the lift and rotate module 150 (shown in FIG. 3), and in this respect may define therein a through-hole or longitudinal slot 316. The intermediate segment 312 of the tube member body 308 extends axially from the actuation end 310 of the tube member body 308 and couples the seat end 304 of the tube member body 308 to the actuation end 310 of the tube member body 308. It is contemplated that the seat end 304 of the tube member body 308 extends from the intermediate segment 312 to an end face 318, is separated from the actuation end 310 of the tube member body 308 by the intermediate segment 312 of the tube member body 308, and is configured to seat the lift pin actuator 200 (shown in FIG. 1).

It is contemplated that the tube member body 308 define a through-bore 320 (shown in FIG. 18) therethrough. The through-bore 320 couples an actuation end aperture 324 defined within an actuation end face 322 on the actuation end 310 to an end face aperture 326 (shown in FIG. 18) defined within the end face 318 on the seat end 304 of the tube member body 308. The through-bore 320 extends continuously and without interruption through the tube member body 308 along the rotation axis 174 and is sized and dimensioned to receive therethrough the shaft member 148 (shown in FIG. 3). In this respect it is contemplated that shaft member 148, when received within the through-bore 320, be separated from the interior surface 302 of the tube member body 308 by a radial gap 328. The radial gap 328 extends circumferentially about the shaft member 148 and axially between the actuation end aperture 324 and the end face aperture 326. As will be appreciated by those of skill in the art in view of the present disclosure, the shaft member 148 is thereby free to rotate about the rotation axis 174 relative to the actuator tube member 300 and the chamber body 130 to rotate the substrate support 142 (shown in FIG. 3) during processing of the substrate 2 (shown in FIG. 3). As will also be appreciated by those of skill in the art in view of the present disclosure, the actuator tube member 300 is thereby also free to translate axially along the rotation axis 174 relative to the shaft member 148 and the chamber body 130 to drive the lift pin actuator 200 between the retracted position 180 (shown in FIG. 5) and the extended position 182 (shown in FIG. 5) to seat and unseat the substrate 2 from the substrate support 142 before and after processing, respectively.

The intermediate segment 312 of the tube member body 308 extends between the actuation end 310 and the seat end 304 of the tube member body 308. In certain examples of the present disclosure the intermediate segment 312 may define an intermediate section diameter 330. The intermediate section diameter 330 may extend continuously and without interruption (span) the intermediate segment 312 of the tube member body 308. It is contemplated that the actuation end 310 of the tube member body 308 may have an actuator end diameter 332. The actuator end diameter 332 may be greater than the intermediate section diameter 330. It is also contemplated that the seat end 304 of the tube member body 308 may define a seat end diameter 334 that is greater than the intermediate section diameter 330. Advantageously, thickening either (or both) the seat end 304 and the actuation end 310 can strengthen the actuator tube member 300, facilitating installation and removal of the actuator tube member 300 from the semiconductor processing system 100 (shown in FIG. 1).

Referring to FIG. 16, the seat end 304 of the tube member body 308 is configured to seat thereon the lift pin actuator 200 and in this respect has a plurality of planar facets 336 defined on an exterior surface 338 of the tube member body 308. It is contemplated that the plurality of planar facets 336 correspond to the plurality of planar faces 250 (shown in FIG. 13) defined by the interior surface 244 (shown in FIG. 13) of the hub portion 208 (shown in FIG. 13) of the lift pin actuator 200 (shown in FIG. 1). In this respect the plurality of planar facets 336 are distributed circumferentially about the rotation axis 174, are equal in number to the plurality of planar faces 250, and are circumferentially spaced about the rotation axis 174 at an angular pitch matching that of the plurality of planar faces 250. In further respect, the plurality of planar facets 336 are further angled relative to the rotation axis 174, each of the plurality of planar facets 336 separated at greater distances from the rotation axis 174 at ends proximate the intermediate segment 312 of the tube member body 308 than at ends proximate the end face 318.

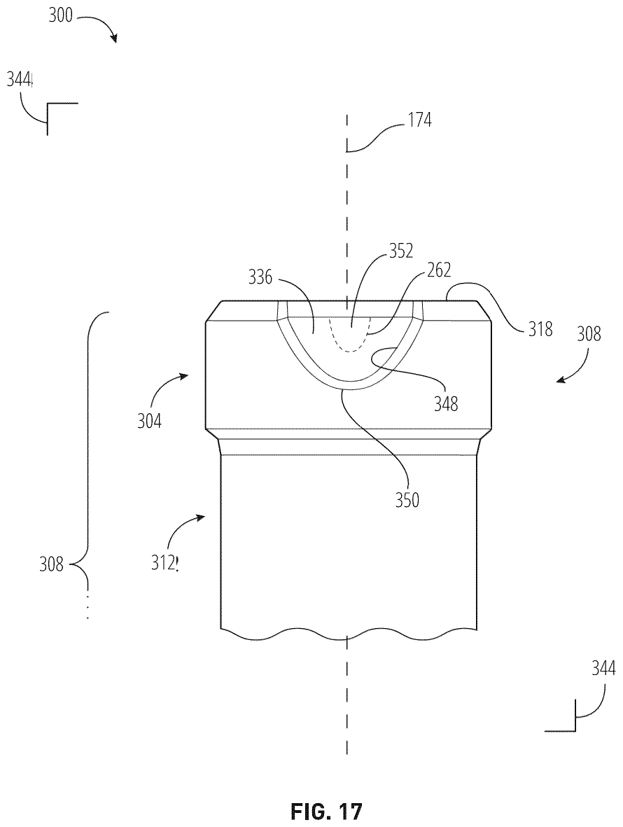

It is contemplated that the plurality of planar facets 336 each be angled relative to the rotation axis 174 (and/or relative to at least one of the actuation end 310 and the exterior surface 338 of the tube member body 308) at a common planar facet angle 340 (shown in FIG. 9). In certain examples, the common planar facet angle 340 may be an oblique angle. In accordance with certain examples, the common planar facet angle 340 may be between about 5 degrees and 45 degrees, or between about 5 degrees and about 30 degrees, or between about 5 degrees and about 15 degrees, or even between about 5 degrees and about 10 degrees. It is contemplated that the common planar facet angle 340 match (e.g., be substantially equivalent to) the common planar face angle 254 (shown in FIG. 9). Advantageously, matching the common planar facet angle 340 to the common planar face angle 254 enables locating the lift pin actuator 200 (shown in FIG. 1) on the actuator tube member 300 using a 3-2-1 locating method. Locating the lift pin actuator 200 on the actuator tube member 300 in turn enables constraining the lift pin actuator 200 in six degrees of freedom relative to the actuator tube member 300 using gravity as a clamping force. In this respect it is contemplated that the lift pin actuator 200 be constrained relative to the actuator tube member 300 in translation and rotation within a first plane 342 (shown in FIG. 16), a second plane 344 (shown in FIG. 17), and a third plane 346 (shown in FIG. 18), limiting (or eliminating) the tendency of the lift pin actuator 200 to pitch or roll due to unequal loads exerted by the plurality of lift pins 144 (shown in FIG. 3) during movement from the retracted position 180 (shown in FIG. 5) to the extended position 182 (shown in FIG. 5).

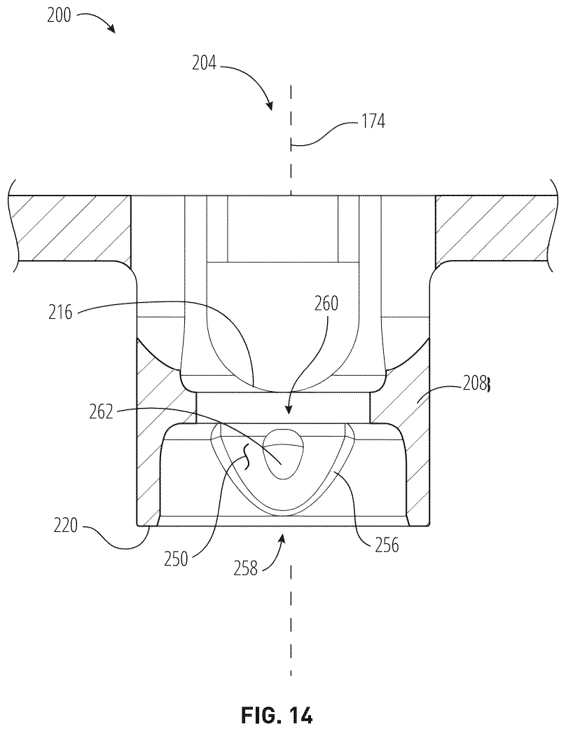

Referring to FIG. 17, it is contemplated that one or more of the plurality of planar facets 336 may be bounded by an arcuate edge 348. The arcuate edge 348 may extend from a base 350, proximate the intermediate segment 312 of the tube member body 308, to an open end 352 proximate the end face 318. In certain examples, the arcuate edge 348 of the one or more of the plurality of planar facets 336 may correspond (e.g., match) the arcuate periphery 256 (shown in FIG. 14) of the lift pin actuator 200 (shown in FIG. 1). In accordance with certain examples, the plurality of planar facets 336 may each have a planar area greater than a planar area of each of the plurality of planar faces 250 defined by the interior surface 244 (shown in FIG. 13) of the hub portion 208 (shown in FIG. 10) of the lift pin actuator 200. Advantageously, this enables locating the lift pin actuator 200 on the actuator tube member 300 using the 3-2-1 locating method at contact points circumferentially spaced about the rotation axis 174, for example at contact points circumferentially separated from one another by the relief channel 262 (shown in FIG. 14). As will be appreciated by those of skill in the art in view of the present disclosure, although shown and described herein as defined within the planar faces 250 (shown in FIG. 14), it is to be understood and appreciated that relief channels may alternatively (or additionally) be defined within one or more of the plurality of planar facets 336 and remain within the scope of the present disclosure.

With continuing reference to FIGS. 13 and 16 as well as with reference to FIG. 18, it is contemplated that the exterior surface 338 of the tube member body 308 define the plurality of arcuate facets 306. The plurality of arcuate facets 306 are distributed circumferentially about the rotation axis 174, separate circumferentially adjacent planar facets 336, and are circumferentially separated from one another by individual ones of the plurality of planar facets 336. It is contemplated that the plurality of arcuate facets 306 be substantially parallel to the rotation axis 174 and are overcut relative to corresponding and radially overlapping ones of the plurality of arcuate faces 252 defined by the interior surface 244 (shown in FIG. 14) of the hub portion 208 (shown in FIG. 10) of the actuator body 204. As shown in FIG. 13, it is further contemplated that (a) each of the planar faces 250 within the lift pin actuator 200 radially overlap a respective one of the plurality of planar facets defined by the seat end 304 of the actuator tube member 300, (b) each of the plurality of arcuate faces 252 defined within the lift pin actuator 200 radially overlap a respective one of the plurality of arcuate facets 354 defined by the seat end 304 of the actuator tube member 300, and (c) each of the plurality of planar faces 250 defined within the lift pin actuator 200 abuts a respective one of the plurality of planar facets 336 defined by the seat end 304 of the actuator tube member 300. Notably, the overcut provides a clearance 356 between radially overlapping ones of the plurality of arcuate faces 252 defined within the hub portion 208 and ones of the plurality of arcuate facets 306 defined by the actuator tube member 300. The clearance 356 in turn causes the lift pin actuator 200 to locate on the plurality of planar facets 336 at the plurality of planar faces 250, promoting stability (e.g., resisting pitch and roll) of the lift pin actuator 200 on the actuator tube member 300.

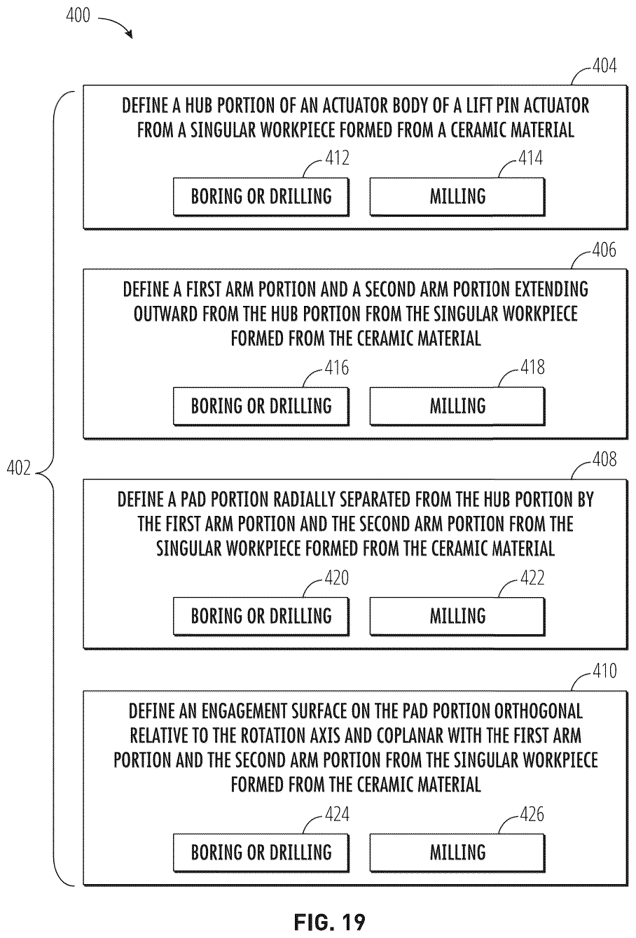

With reference to FIG. 19, a method 400 of making a lift pin actuator, e.g., the lift pin actuator 200 (shown in FIG. 1), is shown. The method 400 includes forming a lift pin actuator body, e.g., the actuator body 204 (shown in FIG. 10), from a singular workpiece body, e.g., the singular workpiece 26 (shown in FIG. 12), formed from a ceramic material, e.g., the ceramic material 206 (shown in FIG. 5), as shown with bracket 402. Forming 402 the lift pin actuator body includes defining a hub portion of the lift pin actuator body from the singular workpiece, e.g., the hub portion 208 (shown in FIG. 10), as shown with box 404. Forming 402 the lift pin actuator body also includes defining a first arm portion and a second arm portion of the lift pin actuator body from the singular workpiece, e.g., the first arm portion 210 (shown in FIG. 10) and the second arm portion 212 (shown in FIG. 10), as shown with box 406. Forming 402 the lift pin actuator body further includes defining a pad portion of the lift pin actuator body from the singular workpiece, e.g., the pad portion 214 (shown in FIG. 10), as shown with box 408. It is contemplated that forming 402 the lift pin actuator body additionally include defining an engagement surface on the pad portion of the lift pin actuator body from the singular workpiece, e.g., the engagement surface 230 (shown in FIG. 12), as shown with box 410.

It is contemplated that one or more of the defining operations 404-410 include forming a portion and/or engagement surface of the lift pin actuator body using two or more subtractive manufacturing techniques. In this respect the hub portion may be formed using a boring or drilling operation and a milling operation, as shown with box 412 and box 414. In further respect, the first arm portion and the second arm portion of the actuator body may be formed using a boring or drilling operation and a milling operation, as shown with box 416 and box 418. It is also contemplated that the pad portion of the actuator body may be formed using a drilling or boring operation and a milling operation, as shown with box 420 and box 422, and that the engagement surface may additionally be formed on the pad portion using a boring or drilling operation and a milling operation, as shown with box 424 and box 426. As will be appreciated by those of skill in the art in view of the present disclosure, forming the actuator body using subtractive manufacturing techniques may limit (or eliminate entirely) the need to weld the actuator body, limiting associated distortion and improving yield of the process used to fabricate the lift pin actuator. As will also be appreciated by those of skill in the art in view of the present disclosure, forming the actuator body using a boring or drilling operation and a milling operation can reduce time required for fabrication of the actuator body due to the relatively high material removal rates associated with boring or drilling in relation to milling ceramic materials, limiting cost of the lift pin actuator.

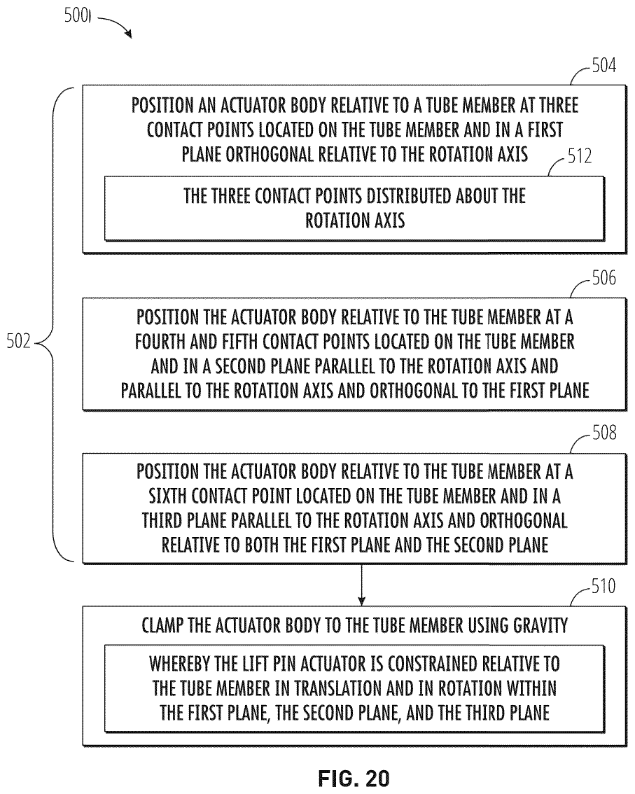

With reference to FIG. 20, a method 500 of making an actuator arrangement, e.g., the actuator arrangement 110 (shown in FIG. 3), is shown. The method 500 includes positioning a lift pin actuator on an actuator tube member according to a 3-2-1 locating method to locate the lift pin actuator on the actuator tube member, e.g., positioning the lift pin actuator 200 (shown in FIG. 1) on the actuator tube member 300 (shown in FIG. 1), as shown with bracket 502. In this respect it is contemplated that positioning 502 the lift pin actuator includes positioning the lift pin actuator relative to the actuator tube member include positioning the lift pin actuator at three (3) contact points located on the actuator tube member in a first plane orthogonal relative to the rotation axis 174, e.g., three (3) of the contact points identified using the 3-2-1 locating method (shown in FIG. 16) in the first plane 342 (shown in FIG. 16), as shown with box 504 and box 512. In further respect, it is also contemplated that positioning 502 the lift pin actuator relative to the actuator tube member includes positioning the lift pin actuator relative to the tube member body at a fourth and a fifth contact points located in a second plane parallel to the rotation axis and orthogonal to the first plane, e.g., two of the six contact points of the 3-2-1 position (shown in FIG. 16) in the second plane 344 (shown in FIG. 17), as shown with box 506.

It is further contemplated that positioning 502 the lift pin actuator relative to the actuator tube member includes positioning the lift pin actuator at a sixth contact point located in a third plane parallel to the rotation axis and orthogonal relative to the first plane and the second plane, e.g., a sixth of the six contact points identified using the 3-2-1 locating method (shown in FIG. 16) lying in the third plane 346 (shown in FIG. 18), as shown with box 508. Positioned according to the 3-2-1 locating method, the lift pin actuator is clamped to the actuator tube member using gravity such that the lift pin actuator is constrained relative to the actuator tube member in translation and in rotation within the first plane, the second plane, and the third plane, as shown with box 510. Advantageously, constrained movement (e.g., roll and pitch) of the lift pin actuator relative to the actuator tube member during operation is limited (or absent entirely), enabling the pad portions of the lift pin actuator to be relatively small. Small pad portions in turn limit shading of the substrate support by the lift pin actuator, improving temperature control of the substrate seated on the substrate support, and limiting cross-substrate variation otherwise induced in the material layer deposited onto the substrate due to cross-substrate temperature variation.

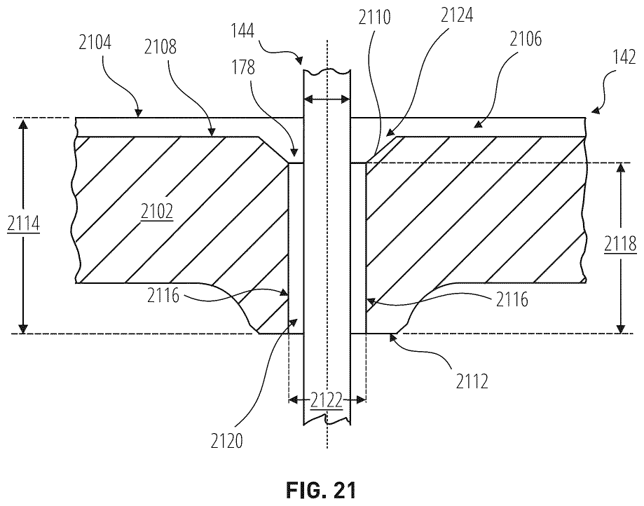

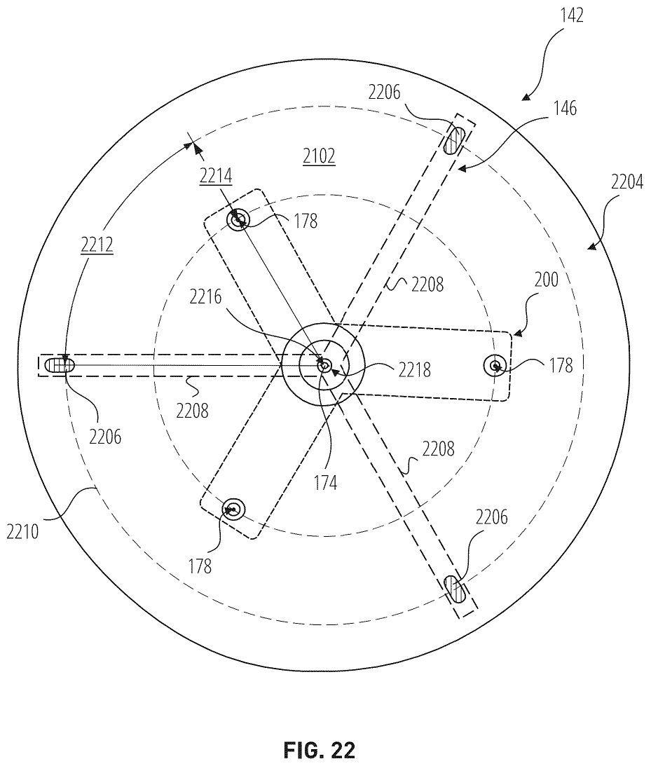

The detailed description below sets forth additional embodiments of substrate support assemblies and methods that may be used with the semiconductor processing apparatus, processing chamber, lift pin actuator, actuator tube member, and actuator positioning arrangements described above. The additional embodiments are provided for purposes of illustration and are not intended to limit the scope of the disclosure or the claims. Unless expressly stated otherwise, features described with respect to FIGS. 21 and 22 may be combined with features described with respect to FIGS. 1-20, and features described with respect to one example may be applied separately from, or in combination with, features described with respect to another example.

FIG. 21 illustrates an example portion of a substrate support 142 that may be used in a substrate support assembly for a semiconductor processing apparatus. The substrate support 142 includes a support body 2102 having an upper surface 2104, an underside surface 2112, a support surface 2108 recessed relative to the upper surface 2104, a substrate retaining region 2106 disposed radially outward from the support surface 2108, and a body thickness 2114 between the upper surface 2104 and the underside surface 2112. The support body 2102 may further include a plurality of support slots 2206 recessed from an underside surface 2204 shown in FIG. 22 and a plurality of lift pin apertures 178 extending through the support body 2102 from respective upper aperture openings 2124 at the support surface 2108 toward the underside surface 2112. Each lift pin aperture 178 may include a recessed portion 2110 at the upper aperture opening 2124 and a guide surface 2116 extending from the recessed portion 2110 toward the underside surface 2112, the guide surface 2116 defining a guide length 2118.

The substrate support assembly may further include a plurality of lift pins 144, a lift pin actuator 200, and a rotation spider 146. Each lift pin 144 may extend through one of the lift pin apertures 178 with a pin clearance 2120 between the lift pin 144 and the guide surface 2116 of the lift pin aperture 178. The lift pin actuator 200 may be positioned adjacent the underside surface of the support body 2102 and may include a plurality of pad portions 214, each pad portion 214 positioned below one of the lift pins 144. The rotation spider 146 may be positioned adjacent the underside surface of the support body 2102 and may include a plurality of support arms 2208 received by the support slots 2206 of the support body 2102. For each lift pin 144 and corresponding lift pin aperture 178, the guide length 2118 and the pin clearance 2120 may be sized to limit tilt of the lift pin 144 relative to the corresponding guide surface 2116 during movement of the lift pin 144 by the lift pin actuator 200.

The support surface 2108 may be distinguished from the upper surface 2104. For example, the upper surface 2104 may define an uppermost surface of the support body 2102, and the support surface 2108 may define a lower substrate-supporting surface of the support body 2102. Accordingly, a substrate supported by the support surface 2108 may be positioned below the upper surface 2104. The substrate may be seated on the support surface 2108 within the substrate retaining region 2106, and the substrate retaining region 2106 may limit lateral movement of the substrate relative to the support body 2102.

The support body 2102 has a body thickness 2114 measured between the upper surface 2104 and the underside surface 2112. As illustrated in FIG. 21, the body thickness 2114 may be measured to the upper surface 2104 rather than to the support surface 2108. FIG. 22 illustrates an underside view of the substrate support 142, including the support body 2102 and the underside surface 2204. The underside surface 2204 shown in FIG. 22 may correspond to the underside surface 2112 described with respect to FIG. 21. Unless the context indicates otherwise, the support body, upper surface, support surface, and underside surface described with respect to FIGS. 21 and 22 refer to the same support body 2102 of the substrate support 142 from different views. The body thickness 2114 of the support body 2102 may be from about 6.35 mm to about 7.75 mm.

The body thickness 2114 may be selected to provide a desired guide length 2118 while maintaining thermal and mechanical characteristics of the support body 2102 for semiconductor processing. The body thickness 2114 may be from about 5 mm to about 9 mm. In examples, the body thickness 2114 may be from about 6 mm to about 8 mm, from about 6.35 mm to about 7.75 mm, about 6.35 mm, or about 7.75 mm. The body thickness 2114 may be selected together with the pin clearance 2120 and the guide length 2118 to limit tilt of the lift pin 144 during movement of the lift pin 144 by the lift pin actuator 200.

FIG. 21 further illustrates a lift pin aperture 178 extending through the support body 2102 from an upper aperture opening 2124 at the support surface 2108 toward the underside surface 2112. The lift pin aperture 178 may receive a lift pin 144 and may allow the lift pin 144 to move relative to the support body 2102 during raising and lowering of a substrate. The recessed portion 2110 may be formed at an upper end of the lift pin aperture 178 and may extend from the upper aperture opening 2124 toward the guide surface 2116. The recessed portion 2110 may provide an enlarged or relieved entry region above the guide surface 2116 and may be sized and configured to seat a head portion of the lift pin 144.

The guide surface 2116 may extend downward from the recessed portion 2110 through at least a portion of the support body 2102 toward the underside surface 2112. A guide length 2118 may be measured along the lift pin aperture 178 from a lower end point of the recessed portion 2110 toward the underside surface 2112. The lower end point of the recessed portion 2110 may be located where the recessed portion 2110 intersects an uppermost portion of the guide surface 2116. Accordingly, the guide length 2118 may correspond to a length of the guide surface 2116 that guides movement of the lift pin 144 below the recessed portion 2110. The guide length 2118 of each lift pin aperture 178 may be from about 5.62 mm to about 7.02 mm.

The guide length 2118 of each lift pin aperture 178 may be from about 4.5 mm to about 8.5 mm. In examples, the guide length 2118 may be from about 5 mm to about 8 mm, from about 5.62 mm to about 7.02 mm, about 5.62 mm, or about 7.02 mm. Increasing the guide length 2118 relative to a shorter guide length may increase the length over which the guide surface 2116 constrains the lift pin 144 and may reduce angular displacement of the lift pin 144 for a given pin clearance 2120.

The lift pin aperture 178 may be sized relative to a pin diameter 2122 of the lift pin 144 to provide the pin clearance 2120 between the lift pin 144 and the guide surface 2116 when the lift pin 144 is received in the lift pin aperture 178. Each lift pin 144 of the plurality of lift pins 144 may have an outer diameter, corresponding to the pin diameter 2122, of about 3.5 mm. For each lift pin 144 and corresponding lift pin aperture 178, the guide length 2118 and the pin clearance 2120 may define a permitted tilt angle of the lift pin 144 relative to the corresponding guide surface 2116, and the permitted tilt angle may be from about 1.621° to about 2.422°.

For each lift pin 144 and corresponding lift pin aperture 178, the guide length 2118 and the pin clearance 2120 may define a permitted tilt angle of the lift pin 144 relative to the corresponding guide surface 2116. The permitted tilt angle may be from about 0.6° to about 3.5°. In examples, the permitted tilt angle may be from about 1° to about 3°, from about 1.621° to about 2.422°, about 1.621°, or about 2.422°. Limiting the permitted tilt angle may reduce contact force between the lift pin 144 and the guide surface 2116 during movement of the lift pin 144 by the lift pin actuator 200, thereby reducing a tendency of the lift pin 144 to bind in the lift pin aperture 178.

The recessed portion 2110 may increase clearance at the upper end of the lift pin aperture 178 relative to the clearance provided along the guide surface 2116. For example, the recessed portion 2110 may reduce contact between the lift pin 144 and an edge of the support surface 2108 adjacent to the upper aperture opening 2124 as the lift pin 144 moves relative to the support body 2102. The recessed portion 2110 may cooperate with the pin clearance 2120 along the guide surface 2116 to permit movement of the lift pin 144 through the support body 2102 while maintaining the support surface 2108 for seating the substrate within the substrate retaining region 2106.

FIG. 22 illustrates an underside layout of the substrate support 142. The substrate support 142 includes the support body 2102 having the underside surface 2204. A plurality of support slots 2206 may be recessed from the underside surface 2204, and a plurality of lift pin apertures 178 may extend through the support body 2102 at locations spaced apart from the support slots 2206. The support slots 2206 may be arranged about a rotation axis 174 and may receive corresponding support arms 2208 of the rotation spider 146 so that the support body 2102 can be supported by the rotation spider 146 from below the underside surface 2204.

The support slots 2206 may be located radially outward from the lift pin apertures 178 relative to the rotation axis 174, such that the lift pin apertures 178 are positioned closer to the rotation axis 174 than the support slots 2206. The support slots 2206 may be arranged on a support slot diameter 2210, which may define a diameter or radial layout on which corresponding portions of the support slots 2206 are positioned about the rotation axis 174. The support arms 2208 of the rotation spider 146 may extend radially outward to the support slots 2206. The support slots 2206 may be arranged about the rotation axis 174 on the support slot diameter 2210 of about 326 mm, and the lift pin apertures 178 may be arranged radially inward of the support slots 2206.

The support slots 2206 and the lift pin apertures 178 may be angularly and radially offset from one another about the rotation axis 174. An angular offset 2212 may define a circumferential spacing between a lift pin aperture 178 and an adjacent support slot 2206 so that the lift pin aperture 178 and a lift pin 144 received therein are angularly displaced from a corresponding support arm 2208. A radial offset 2214 may define a radial spacing between the lift pin apertures 178 and the support slots 2206 relative to the rotation axis 174. Accordingly, the lift pin apertures 178 and the support slots 2206 may be angularly offset about the rotation axis 174 of the support body 2102.

The support body 2102 may further include a center thermocouple hole 2216 extending through the support body 2102 at or near the rotation axis 174. The center thermocouple hole 2216 may provide access for a thermocouple or other temperature-sensing component and may be located radially inward of the support slots 2206. The underside surface 2204 may include a substantially planar central region 2218 surrounding the center thermocouple hole 2216. The center thermocouple hole 2216 may extend through the body thickness 2114 of the support body 2102, and the underside surface 2204 may include the substantially planar central region 2218 surrounding the center thermocouple hole 2216.

FIG. 22 illustrates a rotation-spider engagement interface by which the rotation spider 146 engages and supports the support body 2102 at the underside surface 2204. A separate interface may be provided between the rotation spider 146 and the shaft member 148 to rotate the rotation spider 146 about the rotation axis 174. Thus, the support slots 2206 and support arms 2208 may define an interface between the support body 2102 and the rotation spider 146, while the interface geometry described with reference to FIGS. 13-18 may define an interface between the rotation spider 146 and the shaft member 148.

The clearance 356 may be selected to limit rollover of the lift pin actuator 200 relative to the actuator tube member 300 while maintaining the ability to seat and unseat the lift pin actuator 200 from the actuator tube member 300. The clearance 356 may be defined between the plurality of arcuate faces 252 of the seating socket 242 and the corresponding plurality of arcuate facets 306 of the seat end 304. The clearance 356 may be controlled so that the plurality of planar faces 250 remain located on the plurality of planar facets 336 during movement of the lift pin actuator 200 between the retracted position 180 and the extended position 182. Limiting the clearance 356 may reduce shifting of the lift pin actuator 200 relative to the actuator tube member 300 and may reduce a tendency of the lift pin actuator 200 to roll over, pitch, roll, bind, or lock relative to the actuator tube member 300 during lift pin actuation.

The clearance 356 may be expressed as a radial clearance between a respective arcuate face 252 and a corresponding arcuate facet 306, or as a diametric difference between an inner cylindrical envelope defined by the plurality of arcuate faces 252 and an outer cylindrical envelope defined by the plurality of arcuate facets 306. In examples, the diametric difference may be from about 0.0127 mm to about 0.2 mm. In further examples, the diametric difference may be from about 0.0127 mm to about 0.0889 mm, about 0.15 mm, or about 0.2 mm. The actuator tube member 300 may have a minus tolerance relative to a nominal outer dimension of the plurality of arcuate facets 306, and the hub portion 208 may have a plus tolerance relative to a nominal inner dimension of the plurality of arcuate faces 252, to provide the clearance 356 while allowing assembly of the lift pin actuator 200 onto the actuator tube member 300.

The clearance 356 may cooperate with the common planar face angle 254 and the common planar facet angle 340 to control movement of the lift pin actuator 200 relative to the actuator tube member 300. When the clearance 356 is too large, loads applied to one or more pad portions 214 by the lift pins 144 may allow increased rollover of the lift pin actuator 200 relative to the actuator tube member 300. When the clearance 356 is controlled within a selected range, engagement between the plurality of planar faces 250 and the plurality of planar facets 336 may maintain the 3-2-1 locating relationship while the plurality of arcuate faces 252 and the plurality of arcuate facets 306 limit excessive lateral shifting. The controlled clearance 356 may thereby reduce locking between cylindrical portions of the seating socket 242 and the seat end 304 and may facilitate axial movement of the actuator tube member 300 relative to the lift pin actuator 200 during lift pin operation.

FIGS. 13-18 illustrate interface geometry that may be used to couple a supported member to a rotating member by contact between circumferentially spaced planar faces and corresponding circumferentially spaced planar facets. Although FIGS. 13-18 are described above with reference to the lift pin actuator 200 and the actuator tube member 300, the same interface geometry may be used between the rotation spider 146 and the shaft member 148. In such an arrangement, the rotation spider 146 may include a central interface portion positioned to seat on, and rotate with, the shaft member 148 about the rotation axis 174. The central interface portion of the rotation spider 146 may include the circumferentially spaced planar faces, and the shaft member 148 may include the corresponding circumferentially spaced planar facets.

The substrate support assembly may further include the shaft member 148 supported for rotation about the rotation axis 174. The rotation spider 146 may include the central interface portion coupled to the shaft member 148 and including three circumferentially spaced planar faces. The shaft member 148 may have three circumferentially spaced planar facets, and each planar face may contact a corresponding planar facet to define a circumferential wedge interface between the rotation spider 146 and the shaft member 148. The substrate support assembly may include the substrate support 142, the plurality of lift pins 144, the lift pin actuator 200, the shaft member 148 supported for rotation about the rotation axis 174, and the rotation spider 146 positioned adjacent the underside surface of the support body 2102, the rotation spider 146 including the plurality of support arms 2208 received by the support slots 2206 of the support body 2102 and the central interface portion coupled to the shaft member 148.

Each planar facet of the shaft member 148 may extend along a respective chordal plane that is laterally offset from the rotation axis 174. The three circumferentially spaced planar faces of the rotation spider 146 and the three circumferentially spaced planar facets of the shaft member 148 may each be oriented at an angle of about 10 degrees relative to the rotation axis 174. The angle of the planar faces may correspond to the planar face angle 254 described with respect to FIGS. 13 and 14, and the angle of the planar facets may correspond to the planar facet angle 340 described with respect to FIGS. 15-18.

The three circumferentially spaced planar faces of the rotation spider 146 and the three circumferentially spaced planar facets of the shaft member 148 may each be oriented at an angle from about 6° to about 15° relative to the rotation axis 174. In examples, the angle may be from about 8° to about 12° or about 10°. The angle of the planar faces may correspond to the planar face angle 254 described with respect to FIGS. 13 and 14, and the angle of the planar facets may correspond to the planar facet angle 340 described with respect to FIGS. 15-18. Providing corresponding planar faces and planar facets within these angular ranges may allow the rotation spider 146 to seat on the shaft member 148 while the corresponding planar faces and planar facets constrain relative translation and rotation of the rotation spider 146 and the shaft member 148.

The rotation spider 146 may be seated on the shaft member 148 by a weight of the rotation spider 146, with the three circumferentially spaced planar faces of the rotation spider 146 bearing against the three circumferentially spaced planar facets of the shaft member 148. The three circumferentially spaced planar faces and the three circumferentially spaced planar facets may define three spaced contact regions that constrain relative translation and relative rotation between the rotation spider 146 and the shaft member 148. In this arrangement, the circumferential wedge interface may transmit rotation from the shaft member 148 to the rotation spider 146 while the rotation spider 146 supports the support body 2102 through the support arms 2208 received in the support slots 2206.

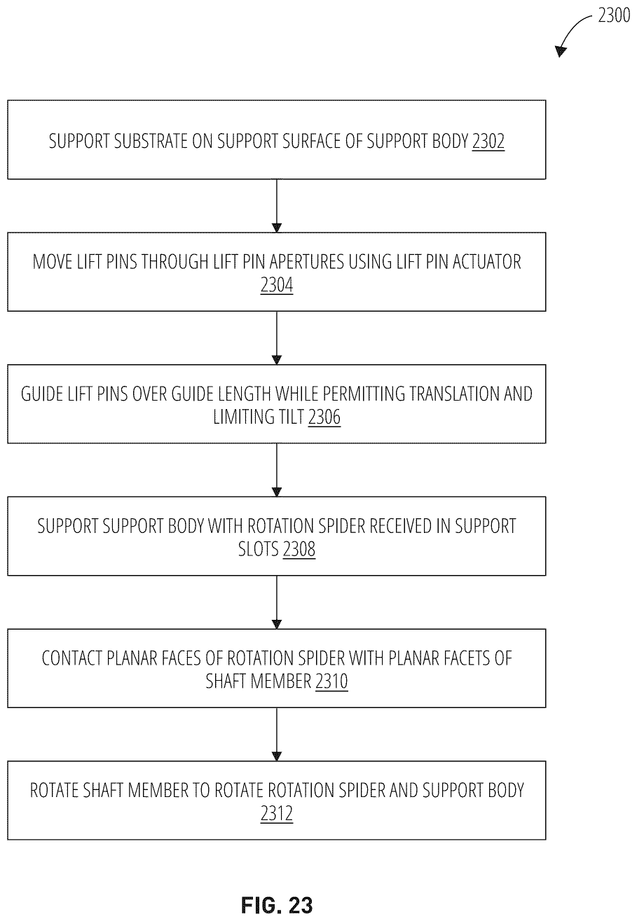

FIG. 23 illustrates a method 2300 of operating a substrate support assembly for a semiconductor processing apparatus. The method 2300 may be performed using the substrate support 142, the support body 2102, the plurality of lift pins 144, the lift pin actuator 200, the rotation spider 146, and the shaft member 148 described above. The method 2300 comprises supporting a substrate on the support surface of the support body (step 2302), moving the lift pins through the lift pin apertures with the lift pin actuator (step 2304), guiding the lift pins over the guide length while permitting translational movement and limiting tilt (step 2306), supporting the support body with the rotation spider received in the support slots (step 2308), contacting planar faces of the rotation spider with planar facets of the shaft member (step 2310), and rotating the shaft member to rotate the rotation spider and the support body (step 2312).

In the supporting step 2302, the substrate may be supported on the support surface 2108 of the support body 2102 of the substrate support 142. As described above with respect to FIGS. 21 and 22, the support body 2102 may include the upper surface 2104, the underside surface 2112, 2204, the body thickness 2114 between the upper surface 2104 and the underside surface 2112, 2204, the substrate retaining region 2106 disposed radially outward from the support surface 2108, the support slots 2206 recessed from the underside surface 2204, and the lift pin apertures 178 extending through the support body 2102 from respective upper aperture openings 2124 at the support surface 2108 toward the underside surface 2112, 2204. Each lift pin aperture 178 may include the recessed portion 2110 at the upper aperture opening 2124 and the guide surface 2116 extending from the recessed portion 2110 toward the underside surface 2112, 2204, the guide surface 2116 defining the guide length 2118.

In the moving step 2304, the lift pin actuator 200 may move the plurality of lift pins 144 through the plurality of lift pin apertures 178. The lift pin actuator 200 may be positioned adjacent the underside surface of the support body 2102 and may include the plurality of pad portions 214, with each pad portion 214 positioned below a corresponding lift pin 144 of the plurality of lift pins 144. Each lift pin 144 may extend through a corresponding lift pin aperture 178 with the pin clearance 2120 between the lift pin 144 and the guide surface 2116 of the corresponding lift pin aperture 178.

In the guiding step 2306, each lift pin 144 may be guided by the guide surface 2116 of the corresponding lift pin aperture 178 over the guide length 2118. The guide length 2118 and the pin clearance 2120 may permit translational movement of the lift pin 144 relative to the corresponding guide surface 2116 and may limit tilt of the lift pin 144 relative to the corresponding guide surface 2116 during movement of the lift pin 144 by the lift pin actuator 200. The recessed portion 2110 at the upper aperture opening 2124 may cooperate with the guide surface 2116 and the pin clearance 2120 as the lift pin 144 moves relative to the support body 2102.

In the supporting step 2308, the support body 2102 may be supported with the rotation spider 146 positioned adjacent the underside surface of the support body 2102. The rotation spider 146 may include the plurality of support arms 2208 received by the plurality of support slots 2206 and the central interface portion coupled to the shaft member 148 supported for rotation about the rotation axis 174. In the contacting step 2310, the three circumferentially spaced planar faces of the central interface portion may contact corresponding ones of the three circumferentially spaced planar facets of the shaft member 148. In the rotating step 2312, the shaft member 148 may be rotated about the rotation axis 174 while each of the three circumferentially spaced planar faces contacts a corresponding one of the three circumferentially spaced planar facets, thereby rotating the rotation spider 146 and the support body 2102 about the rotation axis 174.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

What is claimed:

1. A substrate support assembly for a semiconductor processing apparatus, comprising:
a substrate support comprising:
a support body comprising:
an upper surface, an underside surface, a support surface recessed relative to the upper surface, and a body thickness between the upper surface and the underside surface;
a substrate retaining region disposed radially outward from the support surface;
a plurality of support slots recessed from the underside surface; and
a plurality of lift pin apertures extending through the support body from respective upper aperture openings at the support surface toward the underside surface, each lift pin aperture including a recessed portion at the upper aperture opening and a guide surface extending from the recessed portion toward the underside surface, the guide surface defining a guide length;
a plurality of lift pins, each lift pin extending through one of the lift pin apertures with a pin clearance between the lift pin and the guide surface of the lift pin aperture;
a lift pin actuator positioned adjacent the underside surface of the support body and comprising a plurality of pad portions, each pad portion positioned below one of the lift pins; and
a rotation spider positioned adjacent the underside surface of the support body and comprising a plurality of support arms received by the support slots of the support body,
wherein, for each lift pin and corresponding lift pin aperture, the guide length and the pin clearance are sized to limit tilt of the lift pin relative to the corresponding guide surface during movement of the lift pin by the lift pin actuator.

2. The substrate support assembly of claim 1, wherein for each lift pin and corresponding lift pin aperture, the guide length and the pin clearance define a permitted tilt angle of the lift pin relative to the corresponding guide surface, and wherein the permitted tilt angle is from about 0.6° to about 3.5°.

3. The substrate support assembly of claim 2, wherein the body thickness of the support body is from about 5 mm to about 9 mm.

4. The substrate support assembly of claim 3, wherein the guide length of each lift pin aperture is from about 4.5 mm to about 8.5 mm.

5. The substrate support assembly of claim 1, wherein the lift pin apertures and the support slots are angularly offset about a rotation axis of the support body.

6. The substrate support assembly of claim 1, wherein each lift pin of the plurality of lift pins has an outer diameter of about 3.5 mm.

7. The substrate support assembly of claim 5, wherein the support arms of the rotation spider extend radially outward to the support slots, and wherein the support slots are arranged about the rotation axis on a support slot diameter of about 326 mm.

8. The substrate support assembly of claim 7, wherein the lift pin apertures are arranged radially inward of the support slots.

9. The substrate support assembly of claim 3, wherein the support body comprises a center thermocouple hole extending through the body thickness, and wherein the underside surface comprises a substantially planar central region surrounding the center thermocouple hole.

10. The substrate support assembly of claim 1, further comprising a shaft member supported for rotation about a rotation axis, wherein the rotation spider comprises a central interface portion including three circumferentially spaced planar faces, wherein the shaft member has three circumferentially spaced planar facets, and wherein each planar face contacts a corresponding planar facet to define a circumferential wedge interface between the rotation spider and the shaft member.

11. The substrate support assembly of claim 10, wherein each planar facet of the shaft member extends along a respective chordal plane that is laterally offset from the rotation axis.

12. The substrate support assembly of claim 10, wherein the three circumferentially spaced planar faces and the three circumferentially spaced planar facets are each oriented at an angle from about 6° to about 15° relative to the rotation axis.

13. The substrate support assembly of claim 12, wherein the three circumferentially spaced planar faces and the three circumferentially spaced planar facets are each oriented at an angle of about 10° relative to the rotation axis.

14. The substrate support assembly of claim 13, wherein the three circumferentially spaced planar faces and the three circumferentially spaced planar facets define three spaced contact regions that constrain translation and rotation of the rotation spider relative to the shaft member.

15. A substrate support assembly for a semiconductor processing apparatus, comprising:
a substrate support comprising:
a support body having an upper surface, an underside surface, a support surface recessed relative to the upper surface, and a substrate retaining region disposed radially outward from the support surface;
a plurality of support slots recessed from the underside surface; and
a plurality of lift pin apertures extending through the support body from respective upper aperture openings at the support surface toward the underside surface;
a plurality of lift pins, each lift pin extending through one of the lift pin apertures;
a lift pin actuator positioned adjacent the underside surface of the support body and comprising a plurality of pad portions, each pad portion positioned below one of the lift pins;
a shaft member supported for rotation about a rotation axis; and
a rotation spider positioned adjacent the underside surface of the support body and comprising:
a plurality of support arms received by the support slots of the support body; and
a central interface portion coupled to the shaft member, the central interface portion including three circumferentially spaced planar faces, wherein the shaft member has three circumferentially spaced planar facets, and
wherein each of the three circumferentially spaced planar faces contacts a corresponding one of the three circumferentially spaced planar facets to define a circumferential wedge interface between the rotation spider and the shaft member.

16. The substrate support assembly of claim 15, wherein each planar facet of the shaft member extends along a respective chordal plane that is laterally offset from the rotation axis.

17. The substrate support assembly of claim 15, wherein the three circumferentially spaced planar faces and the three circumferentially spaced planar facets are each oriented at an angle from about 6° to about 15° relative to the rotation axis.

18. The substrate support assembly of claim 15, wherein a weight of the rotation spider seats the rotation spider on the shaft member with the three circumferentially spaced planar faces bearing against the three circumferentially spaced planar facets.

19. The substrate support assembly of claim 18, wherein the three circumferentially spaced planar faces and the three circumferentially spaced planar facets define three spaced contact regions that constrain translation and rotation of the rotation spider relative to the shaft member.

20. A method of operating a substrate support assembly for a semiconductor processing apparatus, the method comprising:
supporting a substrate on a support surface of a support body of a substrate support, the support body having an upper surface, an underside surface, a body thickness between the upper surface and the underside surface, a substrate retaining region disposed radially outward from the support surface, a plurality of support slots recessed from the underside surface, and a plurality of lift pin apertures extending through the support body from respective upper aperture openings at the support surface toward the underside surface, each lift pin aperture including a recessed portion at the upper aperture opening and a guide surface extending from the recessed portion toward the underside surface, the guide surface defining a guide length;
moving a plurality of lift pins through the plurality of lift pin apertures with a lift pin actuator positioned adjacent the underside surface of the support body, the lift pin actuator comprising a plurality of pad portions each positioned below a corresponding lift pin of the plurality of lift pins, and each lift pin extending through a corresponding lift pin aperture with a pin clearance between the lift pin and the guide surface of the corresponding lift pin aperture;
guiding each lift pin with the guide surface of the corresponding lift pin aperture over the guide length while the guide length and the pin clearance permit translational movement of the lift pin relative to the corresponding guide surface and limit tilt of the lift pin relative to the corresponding guide surface during movement of the lift pin by the lift pin actuator;
supporting the support body with a rotation spider positioned adjacent the underside surface of the support body, the rotation spider comprising a plurality of support arms received by the plurality of support slots and a central interface portion coupled to a shaft member supported for rotation about a rotation axis, the central interface portion including three circumferentially spaced planar faces, and the shaft member having three circumferentially spaced planar facets; and
rotating the shaft member about the rotation axis while each of the three circumferentially spaced planar faces contacts a corresponding one of the three circumferentially spaced planar facets, thereby rotating the rotation spider and the support body about the rotation axis.
